(19) United States
(12) Patent Application Publication
(10) Pub. No.: US 2026/0182015 A1
(43) Pub. Date: Jun. 25, 2026

(54) SEMICONDUCTOR DEVICE

(71) Applicant: Samsung Electronics Co., Ltd., Suwon-si (KR)

(72) Inventors: Sangwoo HAN, Suwon-si (KR); Kyuman Hwang, Suwon-si (KR); Jae Hyun Park, Suwon-si (KR); Juhun Park, Suwon-si (KR); Jinchan Yun, Suwon-si (KR); Jae Won Jeong, Suwon-si (KR)

(73) Assignee: Samsung Electronics Co., Ltd., Suwon-si (KR)

(21) Appl. No.: 19/247,802

(22) Filed: Jun. 24, 2025

(30) Foreign Application Priority Data
Dec. 23, 2024 (KR) 10-2024-0194667

(51) Int. Cl. H10D 84/85; H10D 30/00; H10D 30/01; H10D 30/43; H10D 62/10; H10D 62/13; H10D 84/01

(52) U.S. Cl. CPC H10D 84/851; H10D 30/43; H10D 30/502; H10D 62/121; H10D 62/151; H10D 84/856; H10D 30/014; H10D 30/0191; H10D 84/0186; H10D 84/0188

(57) ABSTRACT

A semiconductor device includes: a protruding region that extends in a first direction on a first surface of a lower insulating layer; a device separation layer that is provided at a side of a protruding region, and includes first and second insulating layers on a side surface of the first insulating layer; a lower channel pattern and a lower source/drain pattern that are alternately provided along the first direction above the lower insulating layer; an upper channel pattern above the lower channel pattern; an upper source/drain pattern above the lower source/drain pattern; gate patterns that are spaced apart along the first direction; a gate cutting pattern that extends in the first direction between the gate patterns in a second direction; and a through-via that penetrates the gate cutting pattern and extends on the gate cutting pattern in the first direction and a third direction.

### CROSS-REFERENCE TO RELATED APPLICATION

This application claims priority to Korean Patent Application No. 10-2024-0194667, filed in the Korean Intellectual Property Office, on Dec. 23, 2024, the disclosure of which is incorporated by reference herein in its entirety.

### BACKGROUND

### Field

The present disclosure relates to a three-dimensional semiconductor device.

### Description of Related Art

As a demand for high integration and high performance of a semiconductor device continues to increase, a three-dimensional semiconductor device has recently become a core of a next-generation semiconductor technology. The three-dimensional semiconductor device provides an advantage of greatly improving an electric characteristic and integration of the device by designing a complex three-dimensional structure in a vertical or horizontal direction.

In a manufacturing process of the three-dimensional semiconductor device, formation of an accurate and precise pattern is an important factor that determines performance and reliability of the device. In particular, a step difference occurring between components reduces uniformity in an etching and deposition process to be a major cause of impairing an electric characteristic of the device or reducing a process yield. A step difference problem may be more prominent in the three-dimensional semiconductor device that requires a multi-layer structure and a complex pattern design. Therefore, development of a technology for uniformizing a step difference between components of the three-dimensional semiconductor device is required.

### SUMMARY

One or more embodiments provide a semiconductor device having improved quality may be provided by effectively applying an etching stop layer (or an etching stop film) to reduce alignment variation of components.

According to an aspect of an embodiment, a semiconductor device includes: a protruding region that extends in a first direction on a first surface of a lower insulating layer; a device separation layer that is provided at a side of the protruding region, wherein the device separation layer includes a first insulating layer and a second insulating layer on a side surface of the first insulating layer; a lower channel pattern and a lower source/drain pattern that are alternately provided along the first direction above the lower insulating layer; an upper channel pattern above the lower channel pattern; an upper source/drain pattern above the lower source/drain pattern; gate patterns that are spaced apart along the first direction and surround the lower channel pattern and the upper channel pattern; a gate cutting pattern that extends in the first direction between the gate patterns in a second direction intersecting the first direction; and a through-via that penetrates the gate cutting pattern and extends on the gate cutting pattern in the first direction and a third direction, wherein the third direction intersects the first direction and the second direction.

According to another aspect of an embodiment, a semiconductor device includes: a protruding region that extends in a first direction on a first surface of a lower insulating layer; a device separation layer that is disposed at a side of the protruding region, wherein the device separation layer includes a first insulating layer and a second insulating layer on a side surface of the first insulating layer; a lower channel pattern and a lower source/drain pattern that are alternately provided along the first direction above the lower insulating layer; an upper channel pattern above the lower channel pattern; an upper source/drain pattern above the lower source/drain pattern; gate patterns that are spaced apart along the first direction and surround the lower channel pattern and the upper channel pattern; a gate cutting pattern that extends in the first direction between the gate patterns in a second direction intersecting the first direction; and a through-via that penetrates the gate cutting pattern and extends in a third direction, wherein the third direction intersects the first direction and the second direction.

According to another aspect of an embodiment, a semiconductor device includes: a protruding region that extends in a first direction on a first surface of a lower insulating layer; a device separation layer that is provided at a side of the protruding region, wherein the device separation layer includes a first insulating layer, a second insulating layer on a side surface of the first insulating layer, and a third insulating layer on a side surface of the second insulating layer; a lower channel pattern and a lower source/drain pattern that are alternately provided along the first direction above the lower insulating layer; an upper channel pattern above the lower channel pattern; an upper source/drain pattern above the lower source/drain pattern; gate patterns that are spaced apart along the first direction and surround the lower channel pattern and the upper channel pattern; a gate cutting pattern that extends in the first direction between the gate patterns in a second direction intersecting the first direction; and a through-via that penetrates the gate cutting pattern and extends on the gate cutting pattern in the first direction and a third direction, wherein the third direction intersects the first direction and the second direction.

According to another aspect of an embodiment, a manufacturing method of a semiconductor device according to an embodiment includes: providing a stacking pattern in which first sacrificial layers, first active layers, an intermediate insulating structure, second sacrificial layers, and second active layers are sequentially stacked above a lower pattern on a substrate; forming a first insulating layer covering the lower pattern and the stacking pattern; conformally forming a second insulating layer on the first insulating layer; forming the first insulating layer on the second insulating layer; and recessing the first insulating layer and the second insulating layer to expose the stacking pattern. The first insulating layer and the second insulating layer include different materials.

The manufacturing method may further include forming a third insulating layer on the second insulating layer before the recessing of the first insulating layer and the second insulating layer, and the third insulating layer and the first insulating layer may include a common material.

The manufacturing method may further include: removing the first sacrificial layers and the second sacrificial layers; forming a gate pattern within a region from which the first sacrificial layers and the second sacrificial layers are removed; forming a recess penetrating the gate pattern in a direction perpendicular to the substrate using the second insulating layer as an etching stop layer; and forming a gate cutting pattern that cuts connection of the gate pattern within the recess.

The manufacturing method may further include: forming a recess penetrating at least a portion of the gate cutting pattern in a direction perpendicular to the substrate using the second insulating layer as an etching stop layer; and forming a through-via within the recess.

According to one or more embodiments, a manufacturing quality and productivity of a device may be improved by effectively applying an etching stop layer to reduce alignment variation of components.

### BRIEF DESCRIPTION OF DRAWINGS

The above and other aspects and features will be more apparent from the following description of example embodiments with reference to the attached drawings, in which:

Each of FIG. 1 and FIG. 2 is a plan view showing a semiconductor device according to an embodiment.

FIG. 3 is a cross-sectional view cut along lines A-A′ and D-D′ of each of FIG. 1 and FIG. 2 according to an embodiment.

FIG. 4 is a cross-sectional view cut along a line B-B′ of each of FIG. 1 and FIG. 2 according to an embodiment.

FIG. 5 is a cross-sectional view cut along a line C-C′ of each of FIG. 1 and FIG. 2 according to an embodiment.

Each of FIG. 6 and FIG. 7 is a plan view showing a semiconductor device according to an embodiment.

FIG. 8 is a cross-sectional view cut along lines A-A′ and D-D′ of each of FIG. 6 and FIG. 7 according to an embodiment.

FIG. 9 is a cross-sectional view cut along a line B-B′ of each of FIG. 6 and FIG. 7 according to an embodiment.

FIG. 10 is a cross-sectional view cut along a line C-C′ of each of FIG. 6 and FIG. 7 according to an embodiment.

FIGS. 11 to 56 are cross-sectional views showing a manufacturing method of a semiconductor device according to an embodiment.

### DETAILED DESCRIPTION

Embodiments will be described more fully with reference to the accompanying drawings so that those skilled in the art could easily implement the embodiments. The present disclosure may be modified in various ways, all without departing from the spirit or scope of the present disclosure. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

In order to clearly describe the present disclosure, parts or portions that are irrelevant to the description are omitted, and identical or similar constituent elements throughout the specification are denoted by the same reference numerals.

In the drawings, a size and a thickness of each element are arbitrarily illustrated for ease of description, and the present disclosure is not necessarily limited to those illustrated in the drawings. In the drawings, the thicknesses of some layers and areas are exaggerated for clarity. In the drawings, for ease of description, the thicknesses of some layers and areas are exaggerated.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

Throughout the specification, two directions parallel to and intersecting an upper surface of a substrate are each defined as a first direction D1 and a second direction D2, and a direction perpendicular to the upper surface of the substrate is described as a third direction D3. For example, the first direction D1 and the second direction D2 may be orthogonal to each other.

In the drawings of a semiconductor device according to an embodiment, a 3D stack field effect transistor (3D-SFET) structure is illustrated as an example, but embodiments are not limited thereto. According to an embodiment, the semiconductor device may include a gate all around (GAA) including a nanowire or a nanosheet, a multi-bridge channel field effect transistor (MBCFET™), a FinFET including a fin-type pattern-shaped channel region, a tunneling FET, the 3D stack field effect transistor structure, and a complementary field effect transistor (CFET) structure.

Hereinafter, semiconductor devices according to embodiments will be described with reference to the drawings.

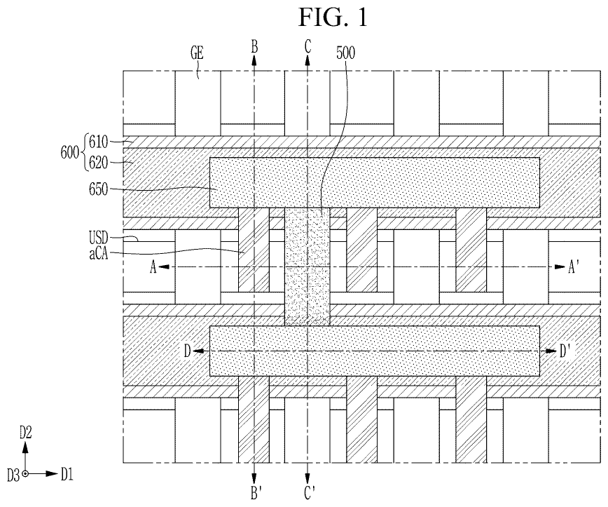

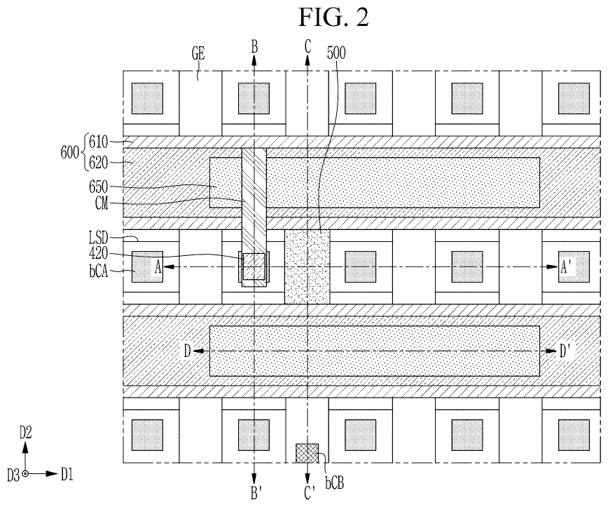

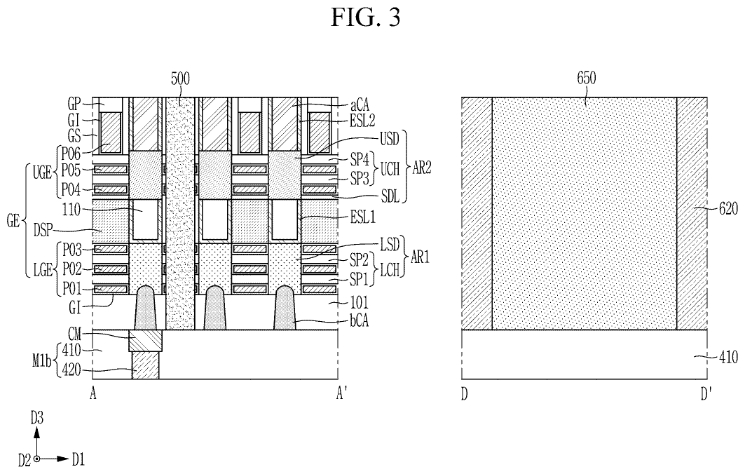

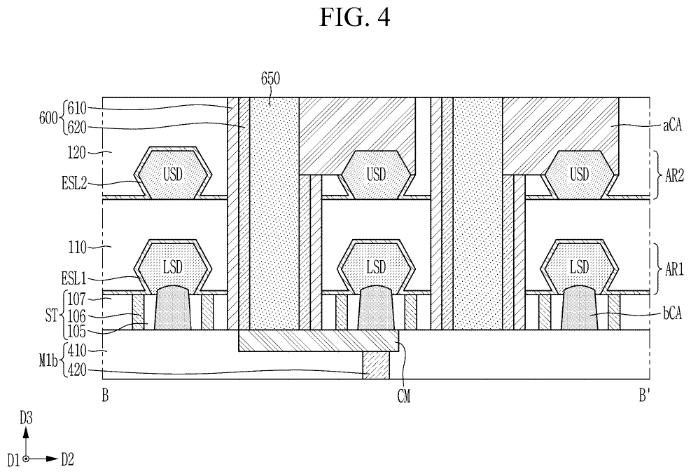

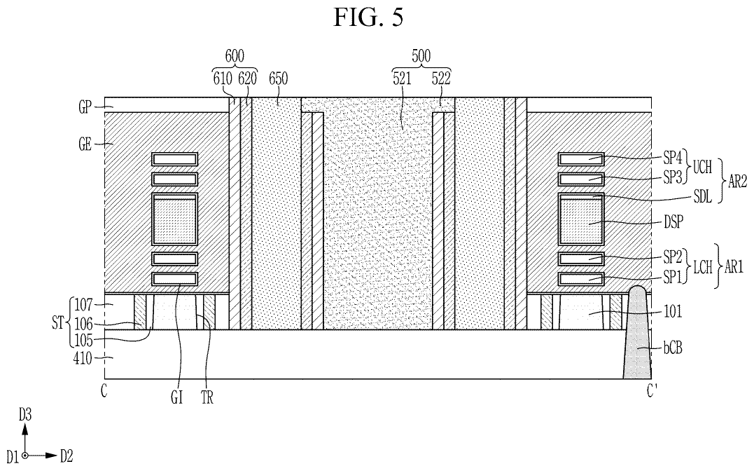

Each of FIG. 1 and FIG. 2 is a plan view showing a semiconductor device according to an embodiment. FIG. 3 is a cross-sectional view cut along lines A-A′ and D-D′ of each of FIG. 1 and FIG. 2 according to an embodiment. FIG. 4 is a cross-sectional view cut along a line B-B′ of each of FIG. 1 and FIG. 2 according to an embodiment. FIG. 5 is a cross-sectional view cut along a line C-C′ of each of FIG. 1 and FIG. 2 according to an embodiment.

FIG. 1 is a plan view showing a first surface (e.g., a front surface) of the semiconductor device according to an embodiment. For clear understanding and simple illustration, FIG. 1 mainly shows a gate pattern GE, an upper source/drain pattern USD, an upper source/drain contact aCA, a separation pattern 500, a gate cutting pattern 600, and a through-via 650.

FIG. 2 is a plan view showing a second surface (e.g., a back surface or a rear surface) of the semiconductor device according to an embodiment. For clear understanding and simple illustration, FIG. 2 mainly shows a lower source/drain pattern LSD, a lower source/drain contact bCA, a lower gate contact bCB, a connection portion CM, a lower wiring layer 420, a separation pattern 500, a gate cutting pattern 600, and a through-via 650.

Referring to FIGS. 1 to 5, the semiconductor device may be a three-dimensional semiconductor device (e.g., a stacked transistor). In this regard, transistors may be stacked in the third direction D3 in a cell region. For example, a single height cell (SHC) may be disposed between a first power wire and a second power wire, the single height cell may include a first active region AR1 as a bottom tier, and a second active region AR2 may be stacked as a top tier above the first active region AR1.

According to an embodiment, the semiconductor device may include a lower insulating layer 410 including first and second surfaces facing each other, and a protruding region 101 extending in the first direction on a first surface (e.g., a front surface) of the lower insulating layer 410.

According to an embodiment, n-type metal-oxide-semiconductor field-effect transistors (NMOSFETs) of the first active region AR1 may be disposed above the protruding region 101, and p-type metal-oxide-semiconductor field-effect transistors (PMOSFETs) of the second active region AR2 may be disposed above the NMOSFETs. The first active region AR1 and the second active region AR2 may be spaced apart from each other in the third direction D3.

In this regard, in the three-dimensional semiconductor device, the first active region AR1 and the second active region AR2 may overlap in the third direction D3. Accordingly, integration of the semiconductor device may be improved due to the reduced area of a logic cell.

In some embodiments, a peripheral region where transistors constituting a processor core or an I/O terminal are disposed may be disposed around the cell region. In this regard, the peripheral region may be a core/peripheral region. For example, the peripheral region may include a long gate transistor (or a long channel transistor) having a relatively long gate length (i.e., a relatively long channel length). A transistor of the peripheral region may be operated with higher electric power than that of a transistor of the cell region. For example, the transistor of the cell region may be a single gate (SG) device, and the transistor of the peripheral region may be an extra gate (EG) device.

As illustrated in FIG. 5, the protruding region 101 may be defined by a trench TR disposed at the cell region. In this regard, the protruding region 101 may be a portion vertically protruding in the third direction D3. On a plane, protruding regions 101 may be spaced apart from each other in the second direction D2, and the protruding region 101 may have a bar shape extending in the first direction D1. The first and second active regions AR1 and AR2 may be sequentially stacked above the protruding region 101.

For example, as described below, the protruding region 101 may be formed by removing a substrate 100 and then replacing the removed substrate with silicon oxide to form the lower source/drain contact bCA. Accordingly, the protruding region 101 may include the silicon oxide.

According to an embodiment, a device separation layer ST may be disposed at both sides of the protruding region 101. For example, the device separation layer ST may fill a trench between protruding regions 101. An upper end portion of the device separation layer ST may be coplanar with an upper end portion of the protruding region 101, or in the third direction D3, a level of the upper end portion of the device separation layer ST may be lower than a level of the upper end portion of the protruding region 101.

According to an embodiment, the device separation layer ST may include a first insulating layer 105, a second insulating layer 106, and a third insulating layer 107. For example, the first insulating layer 105, the second insulating layer 106, and the third insulating layer 107 may be sequentially stacked. In this regard, the second insulating layer 106 may be disposed between the first insulating layer 105 and the third insulating layer 107.

For example, the first insulating layer 105 may be disposed on the protruding region 101, and the second insulating layer 106 may be disposed on a side surface of the first insulating layer 105. The third insulating layer 107 may be buried between the gate cutting pattern 600 and the protruding region 101 described below.

According to an embodiment, the second insulating layer 106 may extend along the third direction D3 from an upper surface of the lower insulating layer 410 to a gate insulating layer GI. A height along the third direction D3 of the second insulating layer 106 may be substantially the same as a height along the third direction D3 of the protruding region 101. However, embodiments are not limited thereto, and the height along the third direction D3 of the second insulating layer 106 may be less than the height along the third direction D3 of the protruding region 101.

According to an embodiment, the first insulating layer 105 and the third insulating layer 107 may include the same material, but embodiments are not limited thereto. According to an embodiment, the second insulating layer 106 may include a different material than those of the first insulating layer 105 and the third insulating layer 107. For example, the second insulating layer 106 may include a material having a different etch rate than those of the first insulating layer 105 and the third insulating layer 107.

For example, each of the first insulating layer 105 and the third insulating layer 107 may include silicon oxide, and the second insulating layer 106 may include silicon nitride.

According to an embodiment, the first active region AR1 including a lower channel pattern LCH and the lower source/drain pattern LSD may be disposed on the protruding region 101. The lower channel pattern LCH may be interposed between one lower source/drain pattern LSD and the other lower source/drain pattern LSD spaced apart from the one lower source/drain pattern LSD in the first direction D1. The lower channel pattern LCH may connect a pair of lower source/drain patterns LSD. For example, the lower channel pattern LCH and the lower source/drain pattern LSD may be alternately disposed in the first direction D1.

According to an embodiment, the lower channel pattern LCH may include a first semiconductor pattern SP1 and a second semiconductor pattern SP2 that are stacked to be spaced apart from each other in the third direction D3. However, embodiments are not limited thereto, and the lower channel pattern LCH may include three or more semiconductor patterns. Each of the first semiconductor pattern SP1 and the second semiconductor pattern SP2 may include silicon (Si), germanium (Ge), or silicon-germanium (SiGe). For example, each of the first semiconductor pattern SP1 and the second semiconductor pattern SP2 may include crystalline silicon.

According to an embodiment, the lower source/drain pattern LSD may be disposed on the upper end portion of the protruding region 101. The lower source/drain pattern LSD may be an epitaxial pattern formed by a selective epitaxial growth (SEG) process. For example, an upper end portion of the lower source/drain pattern LSD may be higher than an upper end portion of the second semiconductor pattern SP2 of the lower channel pattern LCH.

The lower source/drain pattern LSD may be doped with an impurity to have a first conductivity type. The first conductivity type may be an N-type or a P-type. For example, the first conductivity type may be the N-type. The lower source/drain pattern LSD may include silicon (Si) or silicon-germanium (SiGe).

According to an embodiment, the lower source/drain contact bCA may be disposed below the lower source/drain pattern LSD. The lower source/drain contact bCA may penetrate at least a portion of the protruding region 101. For example, the lower source/drain contact bCA may be buried within the protruding region 101. The lower source/drain contact bCA may be disposed below at least one lower source/drain pattern LSD among a plurality of lower source/drain patterns LSD.

According to an embodiment, a lower end portion of the lower source/drain contact bCA may have a flat shape. The lower source/drain contact bCA may be in contact with a lower wiring structure M1b.

According to an embodiment, a first etching stop layer ESL1 may be disposed on the lower source/drain pattern LSD. For example, the first etching stop layer ESL1 may cover the lower source/drain pattern LSD.

According to an embodiment, a first interlayer insulating layer 110 may be disposed on the first etching stop layer ESL1. The first interlayer insulating layer 110 may cover the lower source/drain pattern LSD.

For example, the first interlayer insulating layer 110 may include silicon oxide (SiO₂), silicon nitride (SiN), silicon oxynitride (SiON), or a low dielectric constant material. The low dielectric constant material may be a low k dielectric material having a dielectric constant less than that of silicon oxide.

The first etching stop layer ESL1 may include a material having etch selectivity with respect to the first interlayer insulating layer 110. For example, the first etching stop layer ESL1 may include silicon nitride (SiN), silicon oxynitride (SiON), silicon oxycarbonitride (SiOCN), silicon boronnitride (SiBN), silicon oxyboron nitride (SiOBN), or silicon carbonate (SiOC).

According to an embodiment, the second active region AR2 may be disposed above the first active region AR1. The second active region AR2 may include an upper channel pattern UCH and the upper source/drain pattern USD.

According to an embodiment, the upper channel pattern UCH may be disposed above the lower channel pattern LCH. The upper source/drain pattern USD may be disposed above the lower source/drain pattern LSD. In this regard, the upper channel pattern UCH may overlap the lower channel pattern LCH in the third direction D3. The upper source/drain pattern USD may overlap the lower source/drain pattern LSD in the third direction D3. The upper channel pattern UCH may be interposed between one upper source/drain pattern USD and the other upper source/drain pattern USD spaced apart from the one upper source/drain pattern USD in the first direction D1. The upper channel pattern UCH may connect a pair of upper source/drain patterns USD. For example, the upper channel pattern UCH and the upper source/drain pattern USD may be alternately disposed in the first direction D1.

The upper channel pattern UCH may include a third semiconductor pattern SP3 and a fourth semiconductor pattern SP4 that are stacked to be spaced apart from each other in the third direction D3. However, embodiments are not limited thereto, and the upper channel pattern UCH may include three or more semiconductor patterns. The third semiconductor pattern SP3 and the fourth semiconductor pattern SP4 of the upper channel pattern UCH may include the same semiconductor material as those of the first and second semiconductor patterns SP1 and SP2 of the above-described lower channel pattern LCH.

According to an embodiment, at least one intermediate insulating structure DSP may be interposed between the lower channel pattern LCH and the upper channel pattern UCH, and at least one dummy channel pattern SDL may be interposed between first to fourth semiconductor patterns SP1, SP2, SP3, and SP4.

For example, the intermediate insulating structure DSP may be disposed between the lower channel pattern LCH and the upper channel pattern UCH, and the dummy channel pattern SDL may be interposed between the intermediate insulating structure DSP and the third semiconductor pattern SP3 of the upper channel pattern UCH.

In this regard, the second semiconductor pattern SP2 of the lower channel pattern LCH, a third gate portion PO3 of a lower gate pattern LGE, the intermediate insulating structure DSP, the dummy channel pattern SDL, a fourth gate portion PO4 of an upper gate pattern UGE, and the third semiconductor pattern SP3 of the upper channel pattern UCH may be sequentially stacked in the third direction D3.

The intermediate insulating structure DSP may include a semiconductor material such as silicon (Si), germanium (Ge), or silicon-germanium (SiGe), or may include a silicon-based insulating material such as silicon oxide or silicon nitride.

According to an embodiment, the dummy channel pattern SDL may include a semiconductor material such as silicon (Si), germanium (Ge), or silicon-germanium (SiGe), or may include a silicon-based insulating material such as silicon oxide or silicon nitride.

According to an embodiment, the upper source/drain pattern USD may be disposed on an upper surface of the first interlayer insulating layer 110. The upper source/drain pattern USD may be an epitaxial pattern formed by a selective epitaxial growth (SEG) process. For example, an upper end portion of the upper source/drain pattern USD may be higher than an upper end portion of the fourth semiconductor pattern SP4 of the upper channel pattern UCH.

The upper source/drain pattern USD may be doped with an impurity to have a second conductivity type. The second conductivity type may be different from the first conductivity type of the lower source/drain pattern LSD. For example, the first conductivity type may be an N-type, and the second conductivity type may be a P-type. The upper source/drain pattern USD may include silicon-germanium (SiGe) or silicon (Si).

According to an embodiment, a second etching stop layer ESL2 may be disposed on the upper source/drain pattern USD. For example, the second etching stop layer ESL2 may cover the upper source/drain pattern USD.

The second etching stop layer ESL2 may cover both side surfaces of the upper source/drain pattern USD in the second direction D2. The second etching stop layer ESL2 may not be disposed between the upper source/drain pattern USD and the upper source/drain contact aCA.

A second interlayer insulating layer 120 may be disposed on the second etching stop layer ESL2. The second interlayer insulating layer 120 may cover the upper source/drain pattern USD.

For example, the second interlayer insulating layer 120 may include silicon oxide (SiO₂), silicon nitride (SiN), silicon oxynitride (SiON), or a low dielectric constant material.

The second etching stop layer ESL2 may include a material having etch selectivity with respect to the second interlayer insulating layer 120. For example, the second etching stop layer ESL2 may include silicon nitride (SiN), silicon oxynitride (SiON), silicon oxycarbonitride (SiOCN), silicon boronnitride (SiBN), silicon oxyboron nitride (SiOBN), or silicon carbonate (SiOC).

According to an embodiment, the gate pattern GE may be disposed above the lower channel pattern LCH and the upper channel pattern UCH. On a plane (e.g., FIG. 1), the gate pattern GE may have a bar shape extending in the second direction D2. A portion of the gate pattern GE may overlap a stacked lower channel pattern LCH and upper channel pattern UCH in the third direction D3.

According to an embodiment, the gate pattern GE may extend in the third direction D3 from an upper end portion of the device separation layer ST or an upper end portion of the protruding region 101 to a gate capping pattern GP described later. The gate pattern GE may extend in the third direction D3 from the lower channel pattern LCH of the first active region AR1 to the upper channel pattern UCH of the second active region AR2. In this regard, the gate pattern GE may extend in the third direction D3 from a lowermost first semiconductor pattern SP1 to an uppermost fourth semiconductor pattern SP4.

The gate pattern GE may be disposed above an upper end portion, a bottom surface, and both side surfaces of each of the first semiconductor pattern SP1, the second semiconductor pattern SP2, the third semiconductor pattern SP3, and the fourth semiconductor pattern SP4. In this regard, a logic cell may include a three-dimensional field effect transistor (e.g., an MBCFET or a GAAFET) in which the gate pattern GE three-dimensionally surrounds a channel.

According to an embodiment, the gate pattern GE may have the lower gate pattern LGE and the upper gate pattern UGE sequentially stacked. The lower gate pattern LGE and the upper gate pattern UGE may overlap each other in the third direction D3. The lower gate pattern LGE and the upper gate pattern UGE may be connected to each other. In this regard, the gate pattern GE may be a common gate electrode in which the lower gate pattern LGE above the lower channel pattern LCH and the upper gate pattern UGE above the upper channel pattern UCH are connected to each other.

At least a portion of the gate pattern GE may be disposed above and below a structure in which the lower channel pattern LCH, the intermediate insulating structure DSP, the dummy channel pattern SDL, and the upper channel pattern UCH are alternately stacked. Another portion of the gate pattern GE may be formed to cover both side surfaces of the structure in which the lower channel pattern LCH, the intermediate insulating structure DSP, the dummy channel pattern SDL, and the upper channel pattern UCH are alternately stacked. In this case, four surfaces of each of lower channel patterns LCH and upper channel patterns UCH may be surrounded by the gate pattern GE.

The lower gate pattern LGE may include a first gate portion PO1 interposed between the protruding region 101 and the first semiconductor pattern SP1, a second gate portion PO2 interposed between the first semiconductor pattern SP1 and the second semiconductor pattern SP2, and a third gate portion PO3 interposed between the second semiconductor pattern SP2 and the intermediate insulating structure DSP.

The upper gate pattern UGE may include a fourth gate portion PO4 interposed between the dummy channel pattern SDL and the third semiconductor pattern SP3, a fifth gate portion PO5 interposed between the third semiconductor pattern SP3 and the fourth semiconductor pattern SP4, and a sixth gate portion PO6 disposed above the fourth semiconductor pattern SP4.

For example, the lower gate pattern LGE may include a first work function metal pattern disposed above the first and second semiconductor patterns SP1 and SP2. The upper gate pattern UGE may include a second work function metal pattern disposed above the third and fourth semiconductor patterns SP3 and SP4. Each of the first and second work function metal patterns may include a metal including titanium (Ti), tantalum (Ta), aluminum (AI), tungsten (W), molybdenum (Mo), or a combination thereof, and nitrogen (N). The first and second work function metal patterns may have different work functions. For example, the gate pattern GE may include a low-resistance metal including tungsten (W), ruthenium (Ru), aluminum (Al), titanium (Ti), tantalum (Ta), or a combination thereof on the first and second work function metal patterns.

According to an embodiment, the gate insulating layer GI may be interposed between the gate pattern GE and the first to fourth semiconductor patterns SP1 to SP4. The gate insulating layer may include a silicon oxide layer, a silicon oxynitride layer, a high dielectric layer, or a combination thereof. For example, the gate insulating layer GI may include the silicon oxide layer directly covering surfaces of the first to fourth semiconductor patterns SP1 to SP4 and the high dielectric layer disposed on the silicon oxide layer. In this regard, the gate insulating layer GI may include a multi-layer of the silicon oxide layer and the high dielectric layer.

The high dielectric layer may include a high k dielectric constant material having a higher dielectric constant than that of silicon oxide. For example, the high dielectric constant material may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

In some embodiments, a gate inner spacer may be disposed between the gate pattern GE and the lower source/drain pattern LSD. Additionally, the gate inner spacer may be disposed between the gate pattern GE and the upper source/drain pattern USD. For example, the gate inner spacer may be disposed between the first to third gate portions PO1 to PO3 of the lower gate pattern LGE and the lower source/drain pattern LSD, and may be disposed between the fourth and fifth gate portions PO4 and PO5 of the upper gate pattern UGE and the upper source/drain pattern USD.

For example, in one cross-section, the gate inner spacer may be disposed on both side surfaces in the first direction D1 of each of the first to fifth gate portions PO1 to PO5.

For example, the gate inner spacer may include a k low dielectric constant material. The low dielectric constant material may include silicon oxide, or a material having a lower dielectric constant than that of silicon oxide. For example, the low dielectric constant material may include silicon oxide, silicon oxide doped with fluorine or carbon, porous silicon oxide, or an organic polymer dielectric.

According to an embodiment, a pair of gate spacers GS may be each disposed above both side surfaces in the first direction D1 of the sixth gate portion PO6 of the gate pattern GE. The gate spacers GS may extend in the second direction D2 along the gate pattern GE.

Upper end portions of the gate spacers GS may be higher than an upper end portion of the gate pattern GE. The upper end portions of the gate spacers GS may be coplanar with an upper end portion of the second interlayer insulating layer 120.

The gate spacers GS may include SiCN, SiOCN, SiN, or a combination thereof. For example, the gate spacers GS may include a multi-layer each including SiCN, SiOCN, SiN, or a combination thereof.

According to an embodiment, the gate capping pattern GP may be disposed on an upper end portion of the gate pattern GE. The gate capping pattern GP may extend in the second direction D2 along the gate pattern GE. For example, the gate capping pattern GP may include SiON, SiCN, SiOCN, SiN, or a combination thereof.

According to an embodiment, the gate cutting pattern 600 may be disposed between one protruding region 101 and the other protruding region 101 spaced apart from the one protruding region 101 in the second direction D2. For example, the gate cutting pattern 600 may be disposed between adjacent protruding regions 101 that are spaced apart from one another in the second direction D2. The gate cutting pattern 600 may be spaced apart from the protruding region 101 in the second direction D2, and the device separation layer ST may be disposed between the gate cutting pattern 600 and the protruding region 101.

According to an embodiment, the gate cutting pattern 600 may extend in the first direction D1. For example, on any one plane (e.g., FIG. 1 and FIG. 2), gate cutting patterns 600 may be spaced apart from each other in the second direction D2, and the gate cutting pattern 600 may have a bar shape extending in the first direction D1.

The gate cutting pattern 600 may extend along the third direction D3. For example, the gate cutting pattern 600 may extend along the third direction D3 from a level lower than that of a lower end portion of the gate pattern GE to a level higher than that of an upper end portion of the gate pattern GE. In this regard, a lower end portion of the gate cutting pattern 600 may be disposed closer to a lower end portion of the lower wiring structure M1b in the third direction D3 than the lower end portion of the gate pattern GE.

According to an embodiment, a lower level of the gate cutting pattern 600 may be substantially the same as a lower level of the second insulating layer 106. According to an embodiment, lower levels of gate cutting patterns 600 spaced apart along the second direction D2 may all be substantially the same. Additionally, a lower level of the gate cutting pattern 600 along the third direction D3 may be substantially the same as a lower level of the separation pattern 500 described later. Additionally, the lower level of the gate cutting pattern 600 along the third direction D3 may be substantially the same as a lower level of the through-via 650 described later. The lower level of the gate cutting pattern 600 along the third direction D3 may be substantially the same as a lower level of the lower source/drain contact bCA. The lower end portion of the gate cutting pattern 600 may be in contact with an upper end portion of the lower wiring structure M1b.

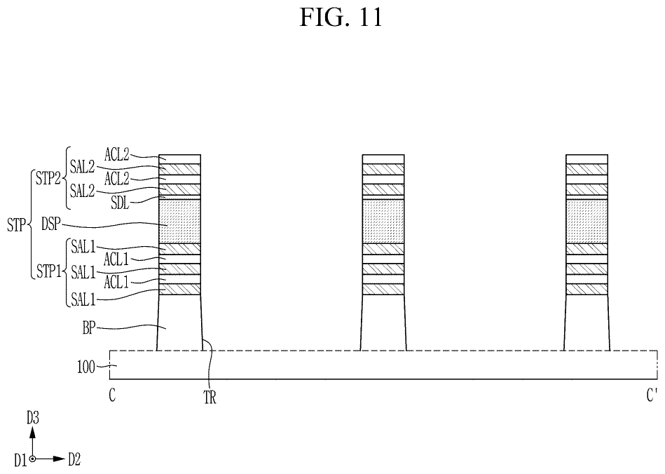

Hereinafter, as described later with reference to FIGS. 11 to 56, because the second insulating layer 106 of the device separation layer ST includes a material having etch selectivity with respect to the first insulating layer 105 and the third insulating layer 107, lower levels of the gate cutting pattern 600, the separation pattern 500, and the through-via 650 along the third direction D3 may all be substantially the same as a lower level of the second insulating layer 106.

The lower level of the gate cutting pattern 600 along the third direction D3 may indicate a shortest distance along the third direction D3 to the lower end portion of the gate cutting pattern 600 based on the lower end portion of the lower wiring structure M1b.

As described above, the semiconductor device according to embodiments may improve an electric characteristic and productivity of the device by reducing alignment variation along the third direction D3 of the components.

According to an embodiment, the gate cutting pattern 600 may be disposed between one lower gate pattern LGE and the other lower gate pattern LGE spaced apart from the one lower gate pattern LGE in the second direction D2. For example, the gate cutting pattern 600 may be disposed between adjacent lower gate patterns LGE that are spaced apart from one another in the second direction D2. Additionally, the gate cutting pattern 600 may be disposed between one upper gate pattern UGE and the other upper gate pattern UGE spaced apart from the one upper gate pattern UGE in the second direction D2. For example, the gate cutting pattern 600 may be disposed between adjacent upper gate patterns UGE that are spaced apart from one another in the second direction D2.

Accordingly, one gate pattern GE may be separated from the other gate pattern GE spaced apart from the one gate pattern GE in the second direction D2 by the gate cutting pattern 600. In this regard, the gate cutting pattern 600 may extend in the first direction D1 across the gate pattern GE, and may penetrate the lower gate pattern LGE and the upper gate pattern UGE of the gate pattern GE. Accordingly, connection of the gate pattern GE may be cut by the gate cutting pattern 600.

According to an embodiment, the gate cutting pattern 600 may be disposed between one lower source/drain pattern LSD and the other lower source/drain pattern LSD spaced apart from the one lower source/drain pattern LSD in the second direction D2. For example, the gate cutting pattern 600 may be disposed between adjacent lower source/drain patterns LSD that are spaced apart from one another in the second direction D2. The gate truncation pattern 600 may be disposed between any one upper source/drain pattern USD and any one upper source/drain pattern USD.

Additionally, the gate cutting pattern 600 may be disposed between one lower source/drain contact bCA and the other lower source/drain contact bCA spaced apart from the one lower source/drain contact bCA in the second direction D2. For example, the gate cutting pattern 600 may be disposed between adjacent lower source/drain contacts bCA that are spaced apart from one another in the second direction D2. In addition, the gate cutting pattern 600 may be disposed between one lower gate contact bCB and the other lower gate contact bCB spaced apart from the one lower gate contact bCB in the second direction D2. For example, the gate cutting pattern 600 may be disposed between adjacent lower gate contacts bCB that are spaced apart from one another in the second direction D2.

As described below, because the separation pattern 500 is formed at a position where the gate pattern GE, the lower channel pattern LCH, and the upper channel pattern UCH are removed after the gate pattern GE, the lower channel pattern LCH, and the upper channel pattern UCH cut by the gate cutting pattern 600 are removed, the gate cutting pattern 600 may be disposed between the gate pattern GE and the separation pattern 500 in the second direction D2. For example, the separation pattern 500 may be disposed between one gate cutting pattern 600 and the other gate cutting pattern 600 spaced apart from the one gate cutting pattern 600 in the second direction D2. For example, the separation pattern 500 may be disposed between adjacent gate cutting patterns 600 that are spaced apart from one another in the second direction D2.

For example, the gate cutting pattern 600 may include a gap-fill insulating layer 620 and an insulating liner 610 disposed at both sides of the gap-fill insulating layer 620 in the second direction D2.

The gap-fill insulating layer 620 may be disposed to fill an inner space of the gate cutting pattern 600. The gap-fill insulating layer 620 may be disposed at an approximately central portion of the gate cutting pattern 600 in the second direction D2.

The insulating liner 610 may be separated at both sides of the gap-fill insulating layer 620 along the second direction D2. For example, the insulating liner 610 may be disposed between the gate pattern GE and the gap-fill insulating layer 620 in the second direction D2, and may be disposed between the separation pattern 500 and the gap-fill insulating layer 620 in the second direction D2.

According to an embodiment, the gate cutting pattern 600 may include an insulating material. For example, the gate cutting pattern 600 may include silicon oxide, silicon nitride, silicon oxynitride, a high dielectric constant (high-k) material having a dielectric constant higher than silicon oxide, or a combination thereof.

For example, the gap-fill insulating layer 620 and the insulating liner 610 constituting the gate cutting pattern 600 may include different materials. For example, the gap-fill insulating layer 620 may include silicon oxide, and the insulating liner 610 may include silicon nitride. However, this is only one example, and materials of the gap-fill insulating layer 620 and the insulating liner 610 may be variously changed.

According to an embodiment, the through-via 650 may be disposed within the gate cutting pattern 600.

According to an embodiment, the through-via 650 may extend in the third direction D3 to penetrate all or at least a portion of the gate cutting pattern 600. An upper portion of the through-via 650 may be connected to the upper source/drain contact aCA, and a lower portion of the through-via 650 may be connected to the lower source/drain contact bCA. Accordingly, the through-via 650 may connect the upper source/drain contact aCA and the lower source/drain contact bCA. Additionally, the through-via 650 may be connected to the lower wiring structure M1b.

As described above, a lower level of the through-via 650 along the third direction D3 may be substantially the same as a lower level of the second insulating layer 106. Additionally, as described above, the lower level of the through-via 650 along the third direction D3 may be substantially the same as a lower level of the gate cutting pattern 600. Additionally, the lower level of the through-via 650 along the third direction D3 may be substantially the same as a lower level of the separation pattern 500 and a lower level of the lower source/drain contact bCA. According to an embodiment, a lower end portion of the through-via 650 may be in contact with an upper end portion of the lower wiring structure M1b.

The lower level of the through-via 650 along the third direction D3 may correspond to a portion of the through-via 650 having a shortest distance along the third direction D3 to the lower wiring structure M1b.

According to an embodiment, the through-via 650 may extend long in the first direction D1 along the gate cutting pattern 600. For example, on any one plane (e.g., FIG. 1 and FIG. 2), through-vias 650 may be spaced apart from each other in the second direction D2, and the through-via 650 may have a bar shape extending in the first direction D1. Accordingly, the through-via 650 may extend in the first direction D1 across the gate pattern GE, and may penetrate the lower gate pattern LGE and the upper gate pattern UGE of the gate pattern GE.

According to an embodiment, the through-via 650 may be disposed at an approximately central portion of the gate cutting pattern 600 in the second direction D2. The insulating liner 610 of the gate cutting pattern 600 may be separated at both sides of the through-via 650 along the second direction D2. The gap-fill insulating layer 620 of the gate cutting pattern 600 may be disposed to fill an inner space between the through-via 650 and the insulating liner 610.

In some embodiments, the through-via 650 may include a conductive pattern and a barrier pattern wrapping the conductive pattern. For example, the conductive pattern may include a metal including aluminum, copper, tungsten, molybdenum, or a combination thereof. The barrier pattern may cover side walls and a bottom surface of the conductive pattern. The barrier pattern may include a metal layer or a metal nitride layer. The metal layer may include titanium, tantalum, tungsten, nickel, cobalt, platinum, or a combination thereof. The metal nitride layer may include a titanium nitride (TiN) layer, a tantalum nitride (TaN) layer, a tungsten nitride (WN) layer, a nickel nitride (NiN) layer, a cobalt nitride (CON) layer, a platinum nitride (PIN) layer, or a combination thereof.

The through-via 650 may be disposed within the gate cutting pattern 600 and the inside of the gate cutting pattern 600 may be filled with the gap-fill insulating layer 620, so that the through-via 650 is surrounded by the gap-fill insulating layer 620. For example, the gap-fill insulating layer 620 may be disposed on both side surfaces of the through-via 650 in the second direction D2.

For example, if the gate cutting pattern 600 includes the gap-fill insulating layer 620 including an oxide and the insulating liner 610 including nitride, etching of the gate cutting pattern 600 for forming the through-via 650 within the gate cutting pattern 600 may be smoothly performed, as described below.

According to an embodiment, the separation pattern 500 may be disposed between one lower source/drain pattern LSD and the other lower source/drain pattern LSD spaced apart from the lower source/drain pattern LSD in the first direction D1. For example, the separation pattern 500 may be disposed between adjacent lower source/drain patterns LSD that are spaced apart from one another in the first direction D1. Additionally, the separation pattern 500 may be disposed between one upper source/drain pattern USD and the other upper source/drain pattern USD spaced apart from the one upper source/drain pattern USD in the first direction D1. For example, the separation pattern 500 may be disposed between adjacent upper source/drain patterns USD that are spaced apart from one another in the first direction D1.

According to an embodiment, the separation pattern 500 may be disposed between one upper source/drain contact aCA and the other upper source/drain contact aCA spaced apart from the one upper source/drain contact aCA in the first direction D1. For example, the separation pattern 500 may be disposed between adjacent source/drain contacts aCA that are spaced apart from one another in the first direction D1. Additionally, the separation pattern 500 may be disposed between one lower source/drain contact bCA and the other lower source/drain contact bCA spaced apart from the one lower source/drain contact bCA in the first direction D1. For example, the separation pattern 500 may be disposed between adjacent lower source/drain contacts bCA that are spaced apart from one another in the first direction D1.

The separation pattern 500 may be disposed between gate patterns GE separated by the gate cutting pattern 600 in the second direction D2. In this regard, the gate cutting pattern 600 may be disposed between the gate pattern GE and the separation pattern 500 in the second direction D2.

The separation pattern 500 may be formed at a position where the gate pattern GE, the lower gate pattern LGE, and the upper gate pattern UGE are removed after at least a portion of the gate pattern GE, the lower gate pattern LGE, and the upper gate pattern UGE are cut by the gate cutting pattern 600. For example, the separation pattern 500 may be disposed between one gate cutting pattern 600 and the other gate cutting pattern 600 spaced apart from the one gate cutting pattern 600 in the second direction D2. For example, the separation pattern 500 may be disposed between adjacent gate cutting patterns LSD that are spaced apart from one another in the second direction D2. The separation pattern 500 may extend in the second direction D2 from one gate cutting pattern 600 to the other gate cutting pattern 600 spaced apart from the one gate cutting pattern 600 in the second direction D2.

Additionally, the separation pattern 500 may be disposed on the same line as that of the gate pattern GE. In this regard, the separation pattern 500 and the gate pattern GE may overlap in the second direction D2, and a width of the separation pattern 500 in the first direction D1 may be similar to or substantially the same as a width of the gate pattern GE in the first direction D1.

The separation pattern 500 may extend in the second direction D2 parallel to the gate pattern GE. For example, on any one plane (e.g., FIG. 1 and FIG. 2), the separation pattern 500 may have a bar shape extending in the second direction D2. In addition, a plurality of separation patterns 500 may be spaced apart in the first direction D1.

According to an embodiment, the separation pattern 500 may extend along the third direction D3. As described above, a lower level of the separation pattern 500 along the third direction D3 may be substantially the same as a lower level of the second insulating layer 106. Additionally, as described above, the lower level of the separation pattern 500 along the third direction D3 may be substantially the same as a lower level of the gate cutting pattern 600. Additionally, the lower level of the separation pattern 500 in the third direction D3 may be substantially the same as a lower level of the through-via 650 and a lower level of the lower source/drain contact bCA. According to an embodiment, a lower end portion of the separation pattern 500 may be in contact with an upper end portion of the lower wiring structure M1b.

For example, the separation pattern 500 may extend along the third direction D3 from a level lower than a lower end portion of the lower source/drain pattern LSD to a level higher than an upper end portion of the upper source/drain pattern USD. In this regard, the lower end portion of the separation pattern 500 may be disposed closer to a lower end portion of the lower wiring structure M1b along the third direction D3 than to the lower end portion of the lower source/drain pattern LSD.

According to an embodiment, the separation pattern 500 may not be spaced apart from the lower wiring structure M1b along the third direction D3. In this regard, the lower end portion of the separation pattern 500 may be in contact with the upper end portion of the lower wiring structure M1b.

The lower level of the separation pattern 500 along the third direction D3 may correspond to a portion of the separation pattern 500 having a shortest distance along the third direction D3 to the lower wiring structure M1b.

For example, the separation pattern 500 may include an insulating material. For example, the separation pattern 500 may include silicon oxide, silicon nitride, silicon oxynitride, a high dielectric constant (high-k) material having a dielectric constant higher than silicon oxide, or a combination thereof.

A portion of the separation pattern 500 may extend in the second direction D2 and may extend into the gate cutting pattern 600. For example, the separation pattern 500 may have a body portion 521 and a protruding portion 522, and the protruding portion 522 of the separation pattern 500 may be inserted into the gate cutting pattern 600. For example, the protruding portion 522 may overlap the gate cutting pattern 600 along the third direction D3. For example, the protruding portion 522 may overlap the insulating liner 610 along the third direction D3. For example, the protruding portion 522 may overlap both the insulating liner 610 and the gap-fill insulating layer 620 along the third direction D3.

According to an embodiment, the body portion 521 may be disposed next to the gate cutting pattern 600 in the second direction D2. The body portion 521 may be disposed between one gate cutting pattern 600 and the other gate cutting pattern 600 spaced apart from the one gate cutting pattern 600 in the second direction D2. For example, the body portion 521 may be disposed between adjacent gate cutting patterns 600 that are spaced apart from one another in the second direction D2. The body portion 521 may extend in the second direction D2 from one gate cutting pattern 600 to the other gate cutting pattern 600 spaced apart from the one gate cutting pattern 600 in the second direction D2. The body portion 521 may be in contact with a side wall of the gate cutting pattern 600 in the second direction D2.

The body portion 521 may extend in the third direction D3. For example, the body portion 521 may extend in the third direction D3 from a level lower than a lower end portion of the lower source/drain pattern LSD to a level higher than an upper end portion of the upper source/drain pattern USD.

According to an embodiment, the protruding portion 522 may protrude from the body portion 521 in the second direction D2. For example, the protruding portion 522 may protrude in the second direction D2 from an upper end portion of the body portion 521. A level of an upper end portion of the protruding portion 522 along the third direction D3 may be substantially the same as a level of the upper end portion of the body portion 521, and a lower level of the protruding portion 522 may be higher than a lower level of the body portion 521. Accordingly, in one cross-section (e.g., FIG. 5), the separation pattern 500 may have a “T” shape.

Because the body portion 521 is in contact with the side wall of the gate cutting pattern 600 in the second direction D2, the protruding portion 522 may be inserted into the gate cutting pattern 600. In this regard, the protruding portion 522 may overlap a portion of the gate cutting pattern 600 in the third direction D3. For example, the protruding portion 522 may pass through the insulating liner 610 of the gate cutting pattern 600 to be disposed on the gap-fill insulating layer 620. Additionally, the protruding portion 522 may be in contact with the through-via 650. For example, the protruding portion 522 may pass through the insulating liner 610 of the gate cutting pattern 600 to be in contact with the through-via 650.

According to an embodiment, the upper source/drain contact aCA may penetrate the second interlayer insulating layer 120 to be electrically connected to the upper source/drain pattern USD. In some embodiments, an upper gate contact may penetrate the second interlayer insulating layer 120 and the gate capping pattern GP to be electrically connected to the gate pattern GE.

The upper source/drain contact aCA may extend in the second direction D2 to be connected to the through-via 650. A portion of the upper source/drain contact aCA may be inserted into the gate cutting pattern 600. In this regard, the portion of the upper source/drain contact aCA may overlap a portion of the gate cutting pattern 600 in the third direction D3. For example, the portion of the upper source/drain contact aCA may pass through the insulating liner 610 of the gate cutting pattern 600 to be disposed on the gap-fill insulating layer 620 and/or the through-via 650. In this case, the portion of the upper source/drain contact aCA may be in contact with the through-via 650. Accordingly, the upper source/drain contact aCA may be connected to the lower source/drain contact bCA through the through-via 650.

In some embodiments, the upper source/drain contact aCA may include a conductive pattern and a barrier pattern wrapping the conductive pattern. For example, the conductive pattern may include aluminum, copper, tungsten, molybdenum, or a combination thereof. The barrier pattern may cover side surfaces and a bottom surface of the conductive pattern. The barrier pattern may include a metal layer or a metal nitride layer. The metal layer may include titanium, tantalum, tungsten, nickel, cobalt, platinum, or a combination thereof. The metal nitride layer may include a titanium nitride (TIN) layer, a tantalum nitride (TaN) layer, a tungsten nitride (WN) layer, a nickel nitride (NiN) layer, a cobalt nitride (CON) layer, a platinum nitride (PtN) layer, or a combination thereof.

In some embodiments, an upper wiring structure connected to the upper source/drain pattern USD may be formed through the upper source/drain contact aCA. The upper wiring structure may include upper wires, upper vias, and an upper insulating layer. Each of the upper wires and the upper vias may include a metal (e.g., copper). The upper insulating layer may be disposed between the upper wires and the upper vias to insulate the upper wires and the upper vias. The upper insulating layer may cover the second interlayer insulating layer 120. The upper wires and the upper vias may be disposed within the upper insulating layer.

According to an embodiment, the lower source/drain contact bCA may be disposed below the lower source/drain pattern LSD, and may be electrically connected to the lower source/drain pattern LSD. For example, the lower source/drain contact bCA may penetrate the protruding region 101 to be electrically connected to the lower source/drain pattern LSD.

According to an embodiment, the connection portion CM may be disposed below the lower source/drain contact bCA and the through-via 650. The connection portion CM may extend in the second direction D2 to connect the lower source/drain contact bCA and the through-via 650. Accordingly, the lower source/drain contact bCA may be connected to the upper source/drain contact aCA through the connection portion CM and the through-via 650.

According to an embodiment, the connection portion CM may be buried within the lower insulating layer 410. According to an embodiment, the connection portion CM may be disposed between the lower wiring layer 420 and the lower source/drain contact bCA in the third direction D3. The connection portion CM may be disposed between the lower wiring layer 420 and the through-via 650 in the third direction D3.

Additionally, the lower gate contact bCB may be disposed below the lower gate pattern LGE, and may be electrically connected to the lower gate pattern LGE. For example, the lower gate contact bCB may penetrate the protruding region 101 or the device separation layer ST to be electrically connected to the lower gate pattern LGE.

In some embodiments, each of the lower source/drain contact bCA and the lower gate contact bCB may include a conductive pattern and a barrier pattern wrapping the conductive pattern. For example, the conductive pattern may include a metal including aluminum, copper, tungsten, molybdenum, or a combination thereof. The barrier pattern may cover side surfaces and a bottom surface of the conductive pattern. The barrier pattern may include a metal layer or a metal nitride layer. The metal layer may include titanium, tantalum, tungsten, nickel, cobalt, platinum, or a combination thereof. The metal nitride layer may include a titanium nitride (TiN) layer, a tantalum nitride (TaN) layer, a tungsten nitride (WN) layer, a nickel nitride (NiN) layer, a cobalt nitride (CoN) layer, a platinum nitride (PtN) layer, or a combination thereof.

According to an embodiment, the lower wiring structure M1b may be disposed below the protruding region 101 or the device separation layer ST. The lower wiring structure M1b may include the lower insulating layer 410 and the lower wiring layer 420 within the lower insulating layer 410.

The lower insulating layer 410 may be disposed below the lower source/drain contact bCA, and may cover lower end portions of the protruding region 101, the device separation layer ST, the lower source/drain contact bCA, the separation pattern 500, the gate cutting pattern 600, and the through-via 650.

The lower insulating layer 410 may include an insulating material, and for example, the lower insulating layer 410 may include silicon oxide, silicon nitride, silicon oxynitride, a low dielectric material, or a combination thereof.

The lower wiring layer 420 may be disposed within the lower insulating layer 410. The lower wiring layer 420 may include lower power wires, lower wires, and lower vias. The lower vias may be disposed on the lower power wires and the lower wires. The lower vias may be each interposed between the lower source/drain contact bCA, the lower gate contact bCB, and the connection portion CM and the lower power wires and the lower wires.

The lower power wires and the lower wires of the lower wiring layer 420 may include the same or different conductive materials. For example, the lower power wires and the lower wires may include aluminum, copper, tungsten, molybdenum, cobalt, or a combination thereof.

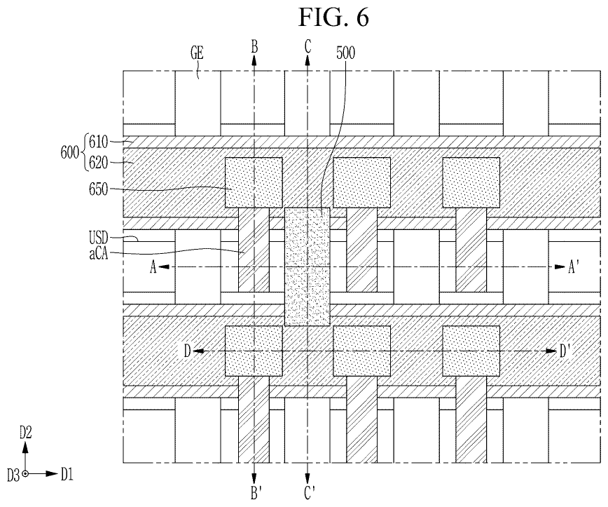

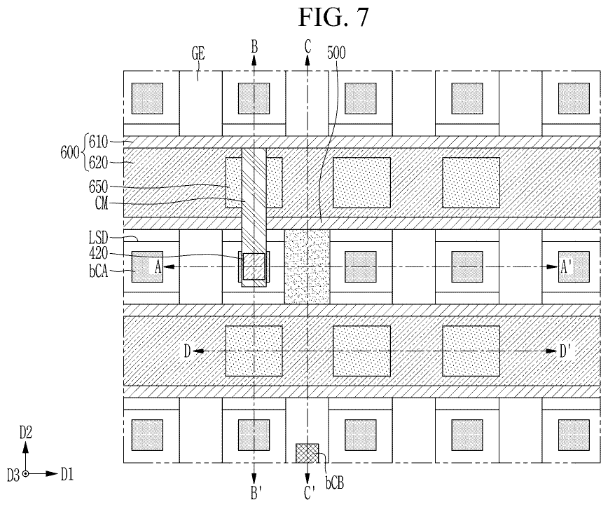

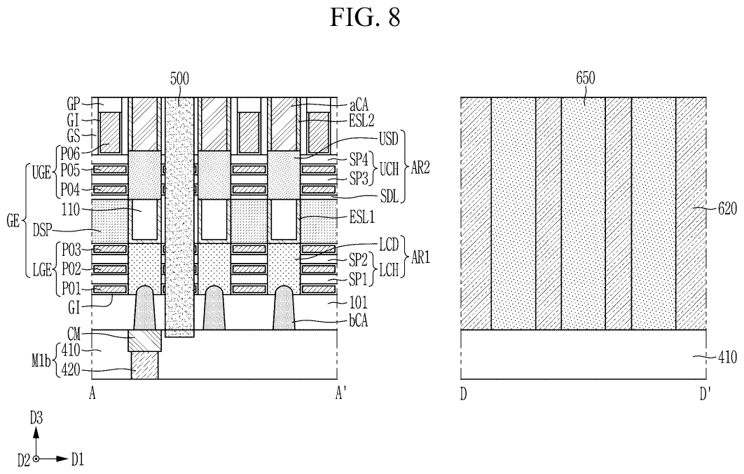

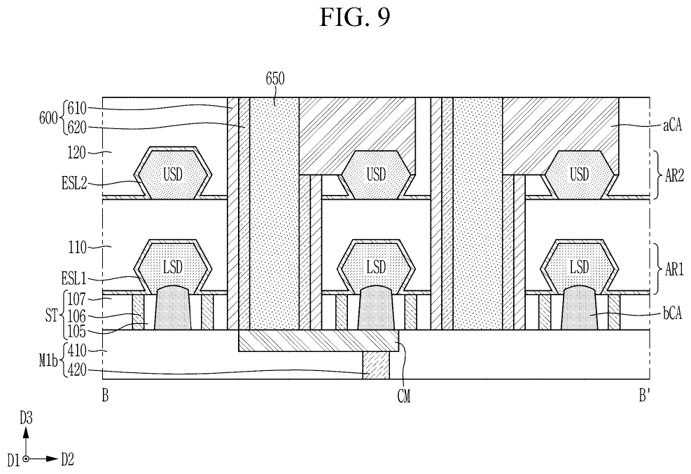

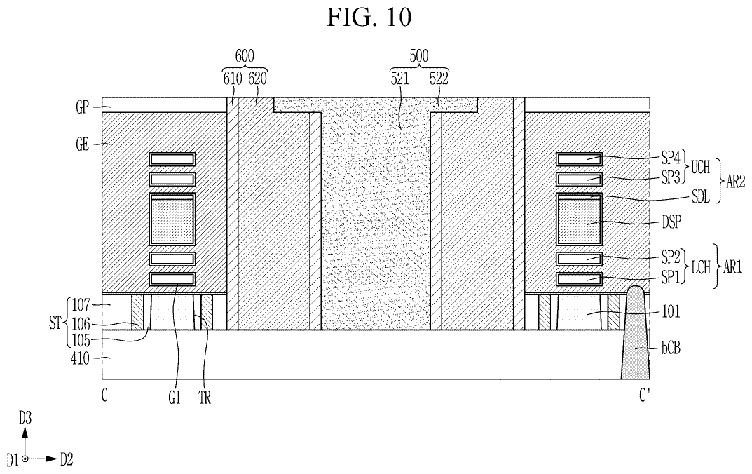

FIG. 6 is a plan view showing a first surface (e.g., a front surface) of a semiconductor device according to an embodiment. FIG. 7 is a plan view showing a second surface (e.g., a back surface or a rear surface) of a semiconductor device according to an embodiment. FIG. 8 is a cross-sectional view cut along lines A-A′ and D-D′ of each of FIG. 6 and FIG. 7 according to an embodiment. FIG. 9 is a cross-sectional view cut along a line B-B′ of each of FIG. 6 and FIG. 7 according to an embodiment. FIG. 10 is a cross-sectional view cut along a line C-C′ of each of FIG. 6 and FIG. 7 according to an embodiment.

The semiconductor device illustrated in FIGS. 6 to 10 may include a component similar to or the same as that of the semiconductor device described with reference to FIGS. 1 to 5. However, unlike the semiconductor device illustrated in FIGS. 1 to 5, the semiconductor device in FIGS. 6 to 10 relates to a structure in which a plurality of through-vias 650 are spaced apart in the first direction D1 within a gate cutting pattern 600. Contents overlapping the contents described with reference to FIGS. 1 to 5 will be simplified or omitted, and differences between the contents described with reference to FIGS. 1 to 5 will be mainly described.

According to an embodiment, the through-via 650 may be disposed within the gate cutting pattern 600. According to an embodiment, the through-vias 650 may be spaced apart from each other in the first direction D1 within the gate cutting pattern 600. In this regard, the through-via 650 may not extend long in the first direction D1 along the gate cutting pattern 600.

According to an embodiment, the through-via 650 may be disposed within the gate cutting pattern 600 and the inside of the gate cutting pattern 600 may be filled with a gap-fill insulating layer 620, so that the through-via 650 is surrounded by the gap-fill insulating layer 620. For example, the gap-fill insulating layer 620 may be disposed on both side surfaces of the through-via 650 in the second direction D2. In addition, for example, the gap-fill insulating layer 620 may be disposed on both side surfaces of the through-via 650 in the first direction D1.

On any one plane (e.g., FIG. 6 and FIG. 7), the through-vias 650 may be alternately disposed with the gap-fill insulating layer 620 of the gate cutting pattern 600 in the first direction D1. As described above, because a lower level of the through-via 650 along the third direction D3 is substantially the same as a lower level of the gate cutting pattern 600, in one cross-section (e.g., FIG. 8), a boundary between the through-via 650 and the gap-fill insulating layer 620 may have a constant shape in the third direction D3 while following the first direction D1.

Additionally, lower levels of the plurality of through-vias 650 along the third direction D3 may be substantially the same as a lower level of a second insulating layer 106. Additionally, the lower levels of the plurality of through-vias 650 along the third direction D3 may be substantially the same as a lower level of the separation pattern 500 and a lower level of a lower source/drain contact bCA. According to an embodiment, lower end portions of the plurality of through-vias 650 may be in contact with an upper end portion of a lower wiring structure M1b.

FIGS. 11 to 56 are cross-sectional views showing a manufacturing method of the semiconductor device according to an embodiment according to a process order.

FIG. 11 is a cross-sectional view corresponding to the line C-C′ of each of FIG. 1 and FIG. 2 according to an embodiment.

Referring to FIG. 11, first and second sacrificial layers SAL1 and SAL2 and first and second active layers ACL1 and ACL2 may be alternately stacked above the substrate 100.

For example, the first sacrificial layer SAL1, the first active layer ACL1, the first sacrificial layer SAL1, the first active layer ACL1, and the first sacrificial layer SAL1 may be sequentially stacked above the substrate 100. The intermediate insulating structure DSP and the dummy channel pattern SDL may be stacked on the first sacrificial layer SAL1. The second sacrificial layer SAL2, the second active layer ACL2, the second sacrificial layer SAL2, and the second active layer ACL2 may be sequentially stacked on the dummy channel pattern SDL.

The substrate 100 may be a semiconductor substrate including silicon, germanium, silicon-germanium, or the like, or a compound semiconductor substrate. For example, the substrate 100 may be a silicon substrate.

According to an embodiment, the first and second sacrificial layers SAL1 and SAL2 may include different materials than those of the first and second active layers ACL1 and ACL2. The first and second sacrificial layers SAL1 and SAL2 may include silicon (Si), germanium (Ge), or silicon-germanium (SiGe), and the first and second active layers ACL1 and ACL2 may include silicon (Si), germanium (Ge), or silicon-germanium (SiGe). For example, the first and second sacrificial layers SAL1 and SAL2 may include the silicon-germanium (SiGe), and the first and second active layers ACL1 and ACL2 may include the silicon (Si).

The first and second sacrificial layers SAL1 and SAL2, the first and second active layers ACL1 and ACL2, the intermediate insulating structure DSP, and the dummy channel pattern SDL that are stacked may be patterned to form a stacking pattern STP.

For example, the stacking pattern STP may be formed by forming a hard mask pattern on an uppermost second active layer ACL2 and etching the stacked layers on the substrate 100 using the hard mask pattern as an etching mask. An upper portion of the substrate 100 may be patterned to form a trench TR defining a lower pattern BP. The stacking pattern STP may have a bar shape extending in the first direction D1.

The stacking pattern STP may include a lower stacking pattern STP1 on the lower pattern BP, and an upper stacking pattern STP2 above the lower stacking pattern STP1. The lower stacking pattern STP1 may include the first sacrificial layers SAL1 and the first active layers ACL1 that are alternately stacked. The upper stacking pattern STP2 may include the second sacrificial layers SAL2 and the second active layers ACL2 that are alternately stacked.

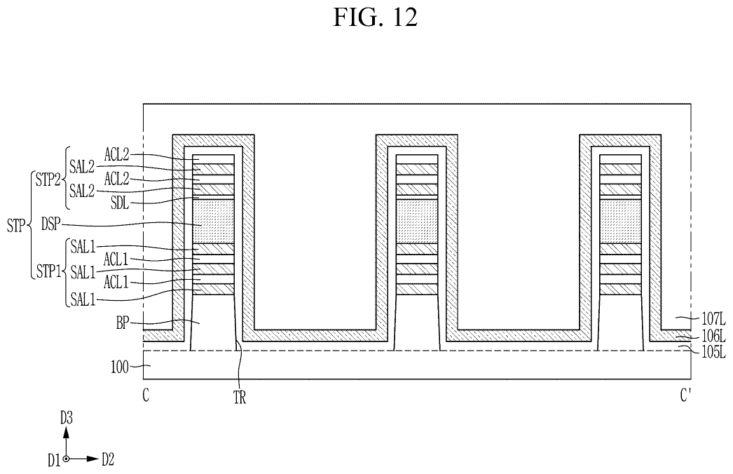

FIG. 12 is a cross-sectional view corresponding to the line C-C′ of each of FIG. 1 and FIG. 2 according to an embodiment.

Referring to FIG. 12, a first material insulating layer 105L, a second material insulating layer 106L, and a third material insulating layer 107L may sequentially fill the inside of the trench TR.

According to an embodiment, the first insulating material layer 105L covering lower patterns BP and stacking patterns STP may be formed on an entire surface of the substrate 100. Next, the second insulating material layer 106L may be formed on the first insulating material layer 105L. For example, the second insulating material layer 106L may be conformally formed on the first insulating material layer 105L. Next, a third insulating material layer 107L may be formed on the second insulating material layer 106L. For example, the third insulating material layer 107L may fill a space of the trench TR that the first material insulating layer 105L and the second material insulating layer 106L do not fill.

According to an embodiment, the first insulating material layer 105L and the third insulating material layer 107L may include the same material, but embodiments are not limited thereto. According to an embodiment, the second insulating material layer 106L may include a different material than those of the first insulating material layer 105L and the third insulating material layer 107L. For example, the second insulating material layer 106L may include a material having a different etch rate than those of the first insulating material layer 105L and the third insulating material layer 107L.

For example, each of the first insulating material layer 105L and the third insulating material layer 107L may include silicon oxide, and the second insulating material layer 106L may include silicon nitride.

FIG. 13 is a cross-sectional view corresponding to the line C-C′ of each of FIG. 1 and FIG. 2 according to an embodiment.

Referring to FIG. 13, the first insulating material layer 105L, the second insulating material layer 106L, and the third insulating material layer 107L may be planarized until upper surfaces of stacking patterns STP are exposed. For example, planarization of the first insulating material layer 105L, the second insulating material layer 106L, and the third insulating material layer 107L may be performed using an etch back process or a chemical mechanical polishing (CMP) process. As a result of the planarization process, the first insulating material layer 105L, the second insulating material layer 106L, and the third insulating material layer 107L may form a coplanar surface with upper surfaces of the stacking patterns STP.

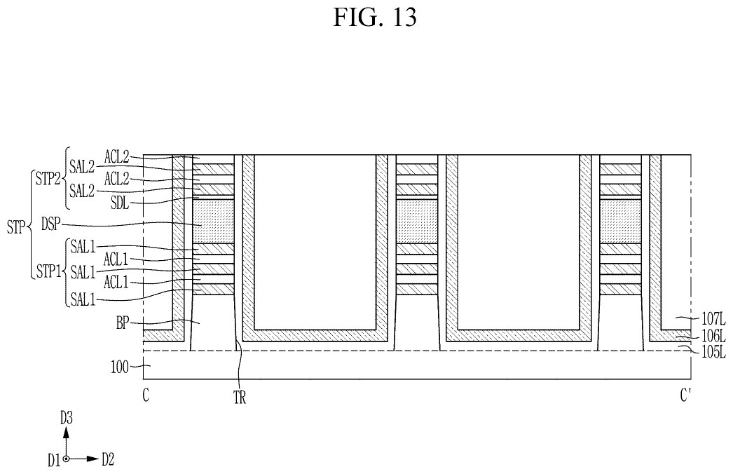

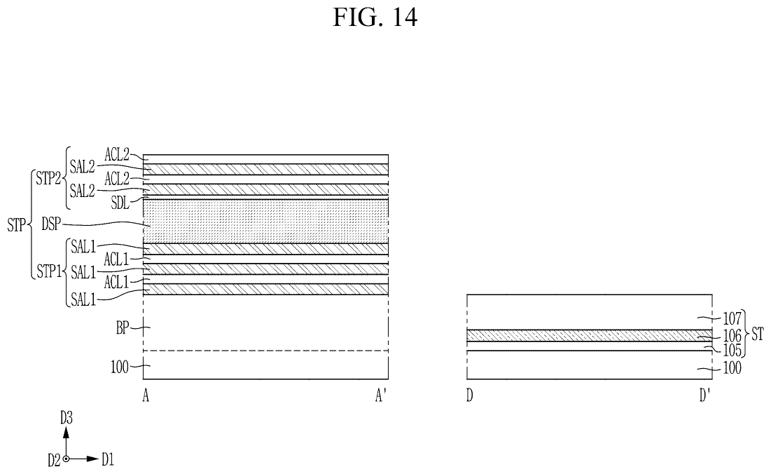

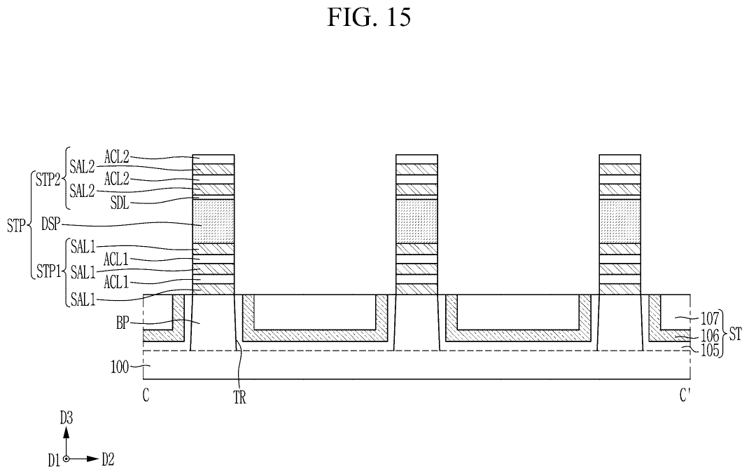

FIG. 14 is a cross-sectional view corresponding to the lines A-A′ and D-D′ of each of FIG. 1 and FIG. 2 according to an embodiment. FIG. 15 is a cross-sectional view corresponding to the line C-C′ of each of FIG. 1 and FIG. 2 according to an embodiment.

Referring to FIG. 14 and FIG. 15, the first insulating material layer 105L, the second insulating material layer 106L, and the third insulating material layer 107L may be recessed to form the device separation layer ST. The third insulating material may be recessed until the stacking patterns STP are exposed.

According to an embodiment, the first insulating material layer 105L, the second insulating material layer 106L, and the third insulating material layer 107L may be recessed until side surfaces of the lower stacking pattern STP1 and the upper stacking pattern STP2 are exposed. Accordingly, the device separation layer ST filling a trench between the lower patterns BP may be formed. In this regard, the lower pattern BP may be defined by the device separation layer ST.

According to an embodiment, an upper end portion of the device separation layer ST may be coplanar with an upper end portion of the lower pattern BP, or a level of the upper end portion of the device separation layer ST may be lower than a level of the upper end portion of the lower pattern BP in the third direction D3.

According to an embodiment, the device separation layer ST may include the first insulating layer 105, a second insulating layer 106, and a third insulating layer 107. For example, the first insulating layer 105, the second insulating layer 106, and the third insulating layer 107 may be sequentially stacked. In this regard, the second insulating layer 106 may be disposed between the first insulating layer 105 and the third insulating layer 107.

According to an embodiment, a portion of the second insulating layer 106 may be parallel to a side wall of the trench TR, and another portion of the second insulating layer 106 may be parallel to a lower surface of the trench TR. A portion parallel to the side wall of the trench TR of the second insulating layer 106 may be referred to as a first portion, and a portion parallel to the lower surface of the trench TR of the second insulating layer 106 may be referred to as a second portion. The first insulating layer 105 may fill a space between the second insulating layer 106 and an inner wall of the trench TR. The third insulating layer 107 may cover the second insulating layer 106.

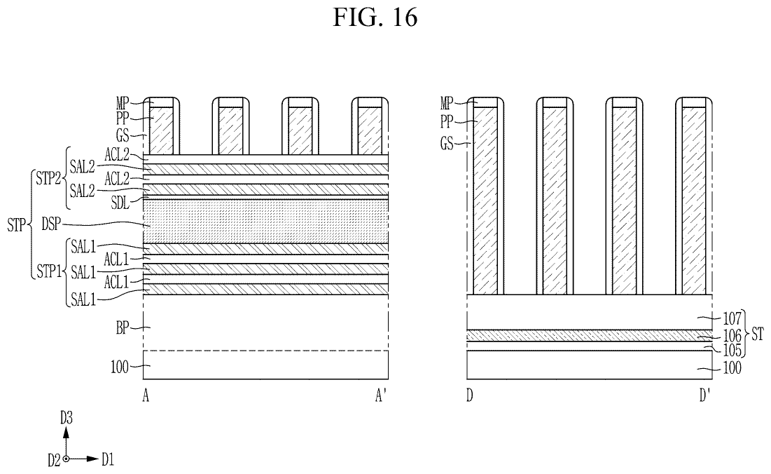

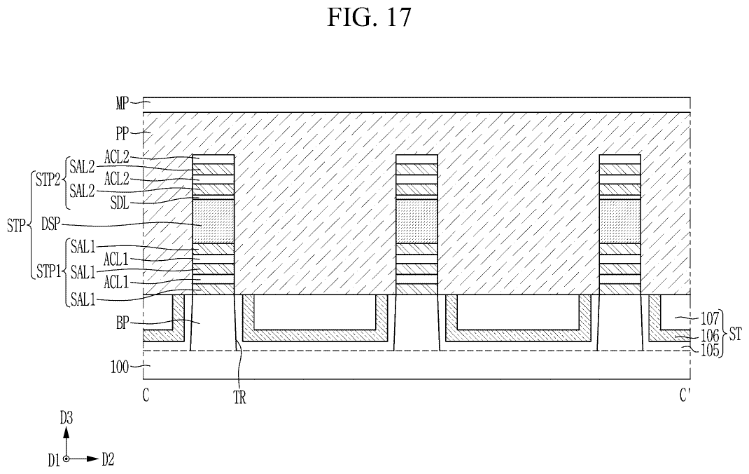

FIG. 16 is a cross-sectional view corresponding to the lines A-A′ and D-D′ of each of FIG. 1 and FIG. 2 according to an embodiment. FIG. 17 is a cross-sectional view corresponding to the line C-C′ of each of FIG. 1 and FIG. 2 according to an embodiment.

Referring to FIG. 16 and FIG. 17, a plurality of sacrificial patterns PP crossing the stacking pattern STP may be formed. Each sacrificial pattern PP may be formed in a line shape extending in the second direction D2. For example, the sacrificial pattern PP may be formed by forming a sacrificial layer on the stacking pattern STP, forming a hard mask pattern on the sacrificial layer, and patterning the sacrificial layer using the hard mask pattern as an etching mask. The sacrificial layer may include amorphous silicon or polysilicon.

Additionally, a preliminary capping layer MP may be formed on the sacrificial pattern PP, and a pair of gate spacers GS may be formed on both side surfaces in the first direction D1 of the sacrificial pattern PP.

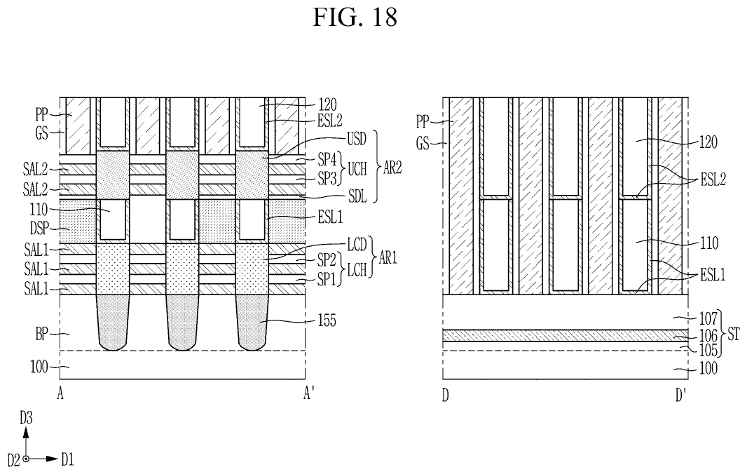

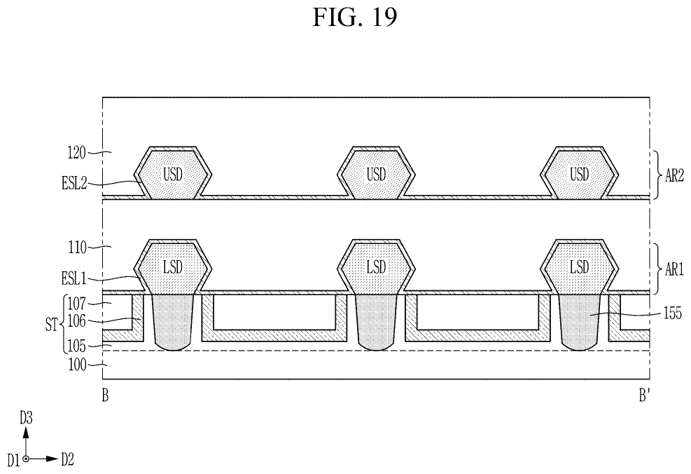

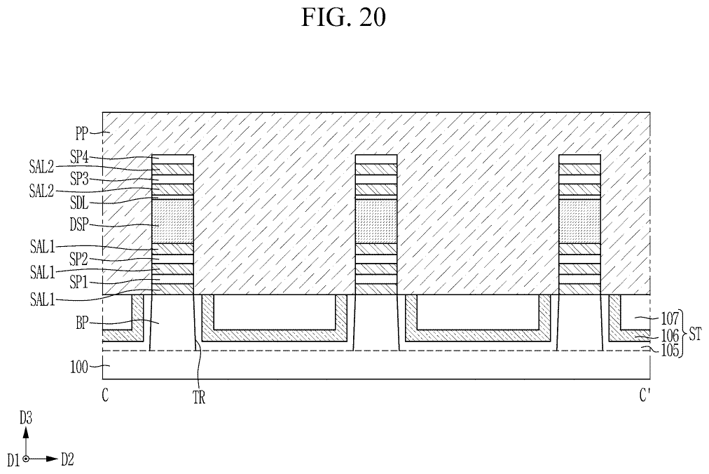

FIG. 18 is a cross-sectional view corresponding to the lines A-A′ and D-D′ of each of FIG. 1 and FIG. 2. FIG. 19 is a cross-sectional view corresponding to the line B-B′ of each of FIG. 1 and FIG. 2. FIG. 20 is a cross-sectional view corresponding to the line C-C′ of each of FIG. 1 and FIG. 2.

Referring to FIGS. 18 to 20, at least a portion of each of the stacking pattern STP and the lower pattern BP may be etched to form recesses using the sacrificial patterns PP, the preliminary capping layer MP, and the gate spacers GS as etching masks. Next, a dummy source/drain pattern 155, the lower source/drain pattern LSD, the first etching stop layer ESL1, the first interlayer insulating layer 110, the upper source/drain pattern USD, the second etching stop layer ESL2, and the second interlayer insulating layer 120 may be sequentially formed within the recesses.

For example, the dummy source/drain pattern 155 may include a material different from that of the lower source/drain pattern LSD. Alternatively, the dummy source/drain pattern 155 may include a material having etch selectivity with respect to the lower source/drain pattern LSD.

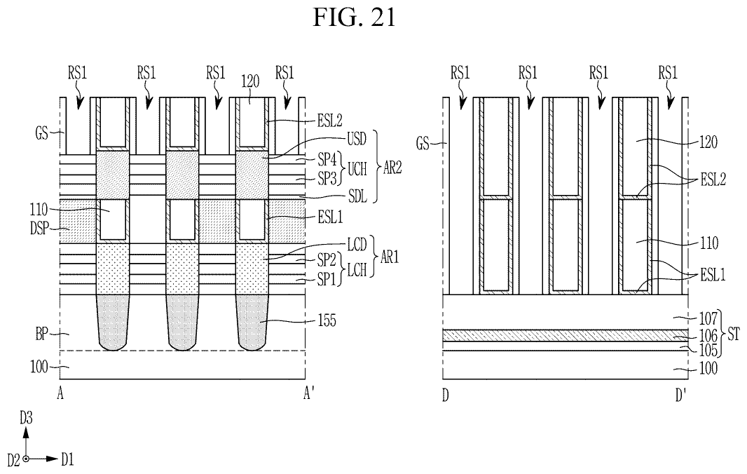

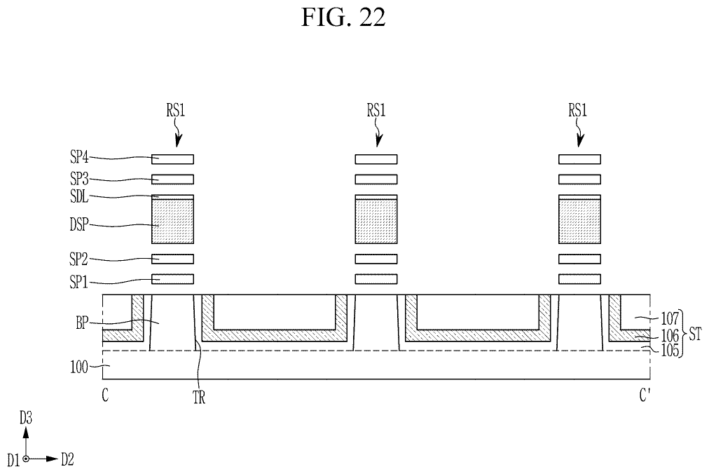

FIG. 21 is a cross-sectional view corresponding to the lines A-A′ and D-D′ of each of FIG. 1 and FIG. 2. FIG. 22 is a cross-sectional view corresponding to the line C-C′ of each of FIG. 1 and FIG. 2. In this case, a cross-sectional view cut along the line B-B′ of each of FIG. 1 and FIG. 2 may be the same as FIG. 19 so that the cross-sectional view cut along the line B-B′ of each of FIG. 1 and FIG. 2 is omitted.

Referring to FIG. 21 and FIG. 22, the preliminary capping layer MP may be removed to expose the sacrificial pattern PP, and first recesses RS1 may be formed by removing the exposed sacrificial pattern PP.

For example, removal of the sacrificial pattern PP may use wet etching using an etchant that selectively etches polysilicon. The first and second sacrificial layers SAL1 and SAL2 may be exposed by removing the sacrificial pattern PP.

Next, an etching process that selectively etches the exposed first and second sacrificial layers SAL1 and SAL2 may be performed so that only the first and second sacrificial layers SAL1 and SAL2 are removed while the first to fourth semiconductor patterns SP1 to SP4 remain as they are.

For example, the etching process of the first and second sacrificial layers SAL1 and SAL2 may have a high etch rate with respect to silicon-germanium. For example, the etching process may have a high etch rate with respect to silicon-germanium having a germanium concentration greater than 10 at %.

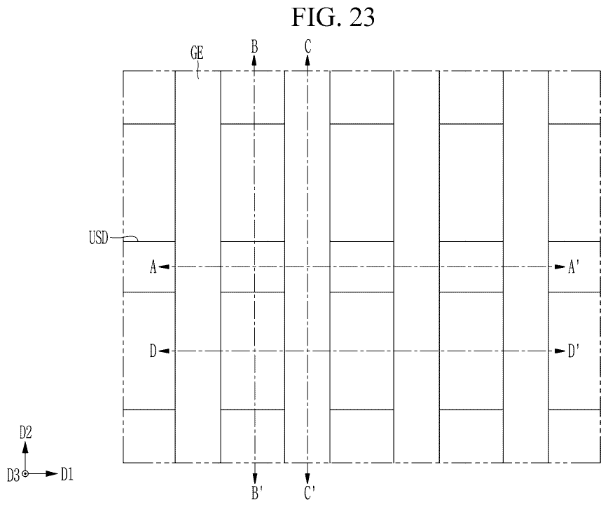

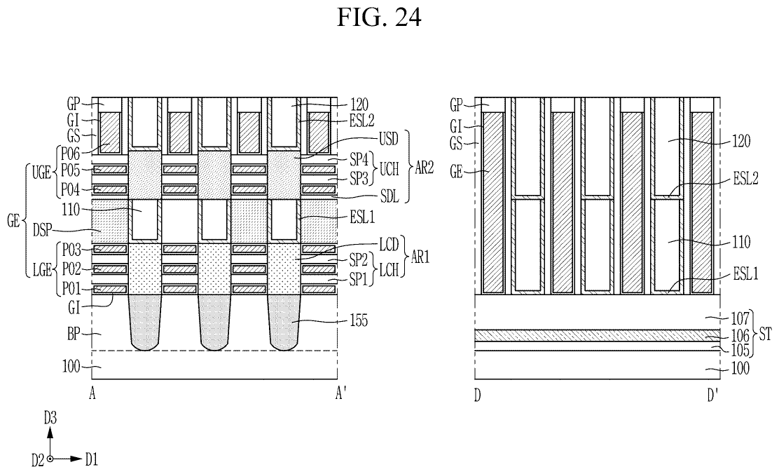

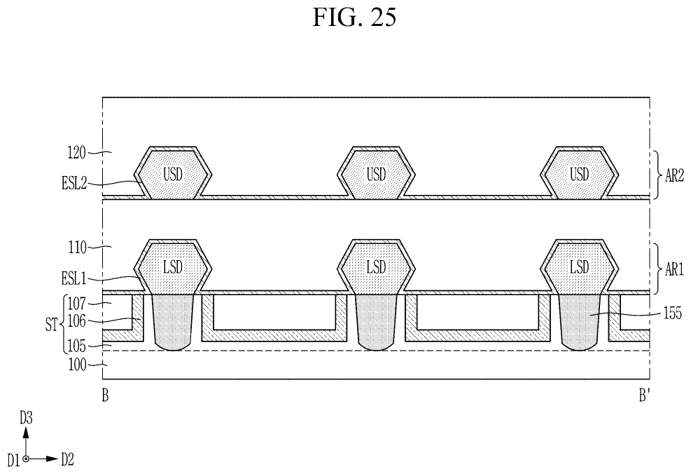

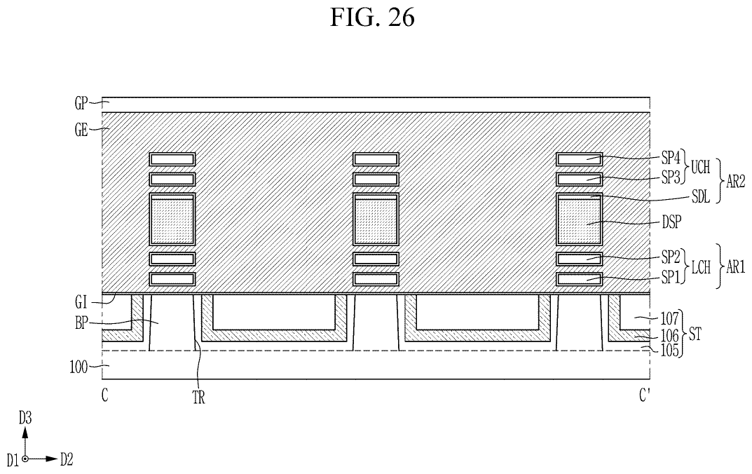

FIG. 23 is a plan view showing a first surface (e.g., a front surface) of a semiconductor device according to an embodiment. FIG. 24 is a cross-sectional view cut along lines A-A′ and D-D′ of FIG. 23 according to an embodiment. FIG. 25 is a cross-sectional view cut along a line B-B′ of FIG. 23 according to an embodiment. FIG. 26 is a cross-sectional view cut along a line C-C′ of FIG. 23 according to an embodiment.

Referring to FIGS. 23 to 26, a gate pattern GE may be formed within a region where a sacrificial pattern PP and first and second sacrificial layers SAL1 and SAL2 are removed.

First, a gate insulating layer GI may be conformally formed within the region where the sacrificial pattern PP and the first and second sacrificial layers SAL1 and SAL2 are removed.

Next, the gate pattern GE may be formed on the gate insulating layer GI. Formation of the gate pattern GE may be performed by forming a lower gate pattern LGE including first to third gate portions PO1 to PO3 between first semiconductor patterns SP1 and forming an upper gate pattern UGE including fourth to sixth gate portions PO4 to PO6 between second semiconductor patterns SP2.

The gate pattern GE may be recessed so that a height thereof is reduced. A gate capping pattern GP may be formed on the recessed gate pattern GE. A planarization process may be performed on the gate capping pattern GP so that the upper surface of the gate capping pattern GP is coplanar with the upper surface of the second interlayer insulating layer 120.

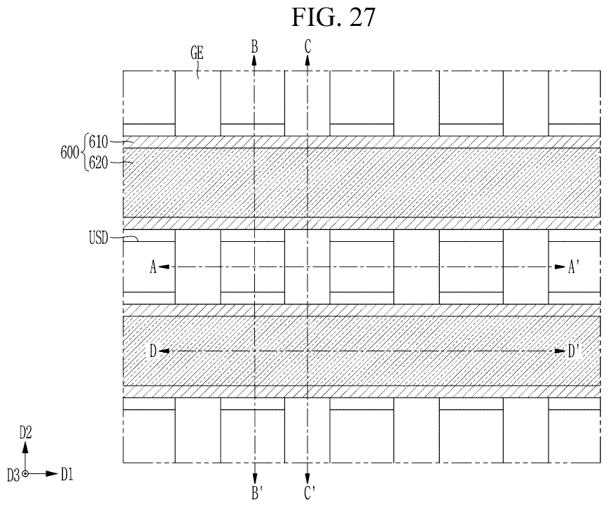

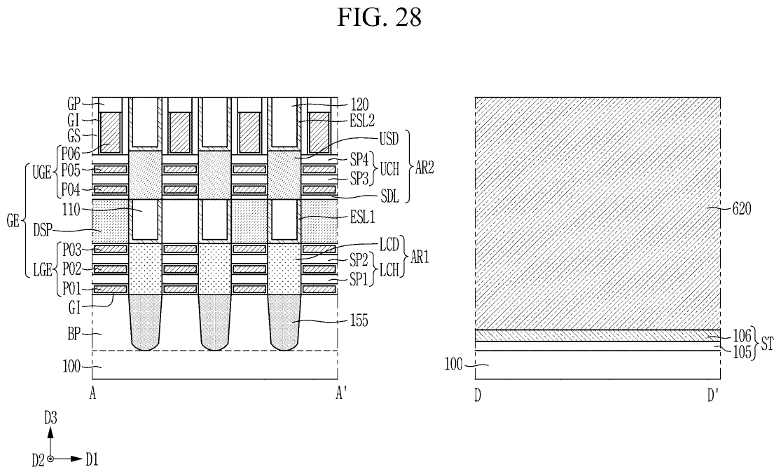

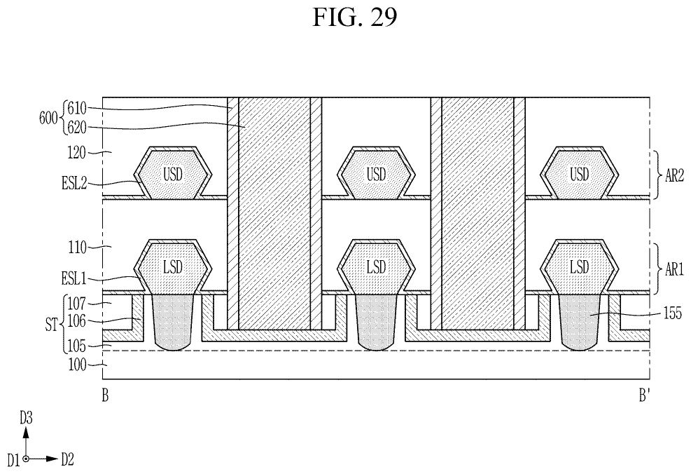

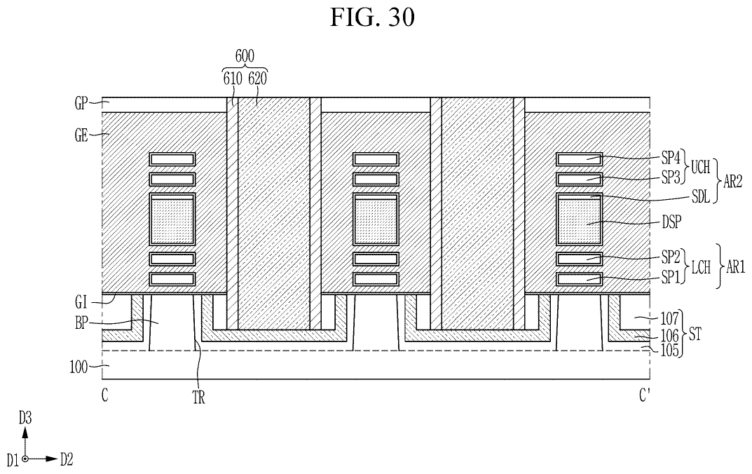

FIG. 27 is a plan view showing a first surface (e.g., a front surface) of a semiconductor device according to an embodiment. FIG. 28 is a cross-sectional view cut along lines A-A′ and D-D′ of FIG. 27 according to an embodiment. FIG. 29 is a cross-sectional view cut along a line B-B′ of FIG. 27 according to an embodiment. FIG. 30 is a cross-sectional view cut along a line C-C′ of FIG. 27 according to an embodiment.

Referring to FIGS. 27 to 30, a gate cutting pattern 600 extending in the first direction D1 while crossing a gate pattern GE to cut connection of the gate pattern GE may be formed.

According to an embodiment, a hard mask pattern may be formed on a gate capping pattern GP and the gate pattern GE may be etched using the hard mask pattern as an etching mask to form a recess. In this case, a second insulating layer 106 may act as an etching stop layer. For example, the recess may be formed from an upper end portion of the gate capping pattern GP to an upper end portion of the second insulating layer 106 along the third direction D3. Specifically, a second portion of the second insulating layer 106 may act as the etching stop layer so that the recess is formed on the second portion of the second insulating layer 106.

The gate cutting pattern 600 may be formed by conformally applying an insulating liner 610 to a region where the gate pattern GE is removed and then filling a space between insulating liners 610 with a gap-fill insulating layer 620.

According to an embodiment, a lower level of the gate cutting pattern 600 along the third direction D3 may be substantially the same as an upper level of the second portion of the second insulating layer 106.

According to the manufacturing method of the semiconductor device according to embodiments, the second portion of the second insulating layer 106 may act as the etching stop layer so that all lower levels of gate cutting patterns 600 are substantially the same. More specifically, as the second insulating layer 106 has an etch rate that is different from that of the first insulating layer 105 and the third insulating layer 107, the second insulating layer 106 may act as the etching stop layer resulting in the lower levels of the gate cutting patterns 600 along the third direction D3 being constant. Therefore, the second insulating layer 106 reduces alignment variation along the third direction D3.

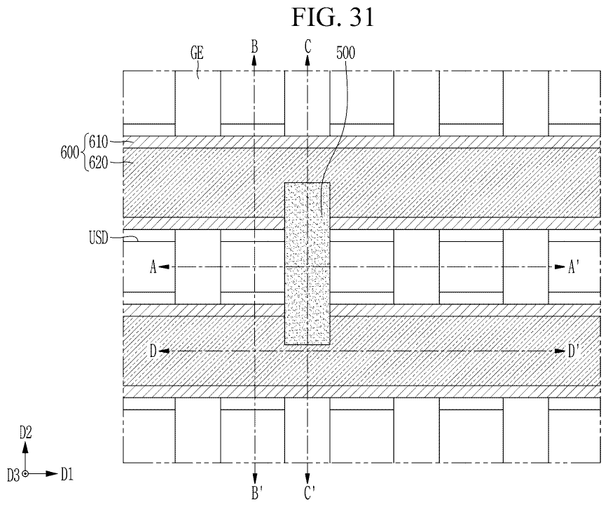

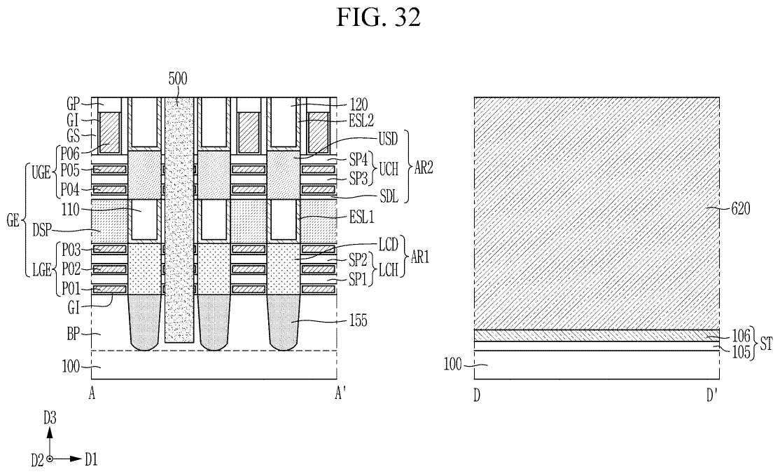

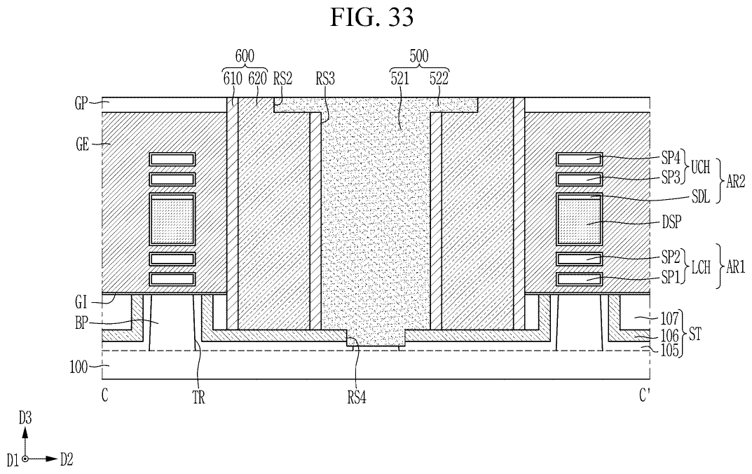

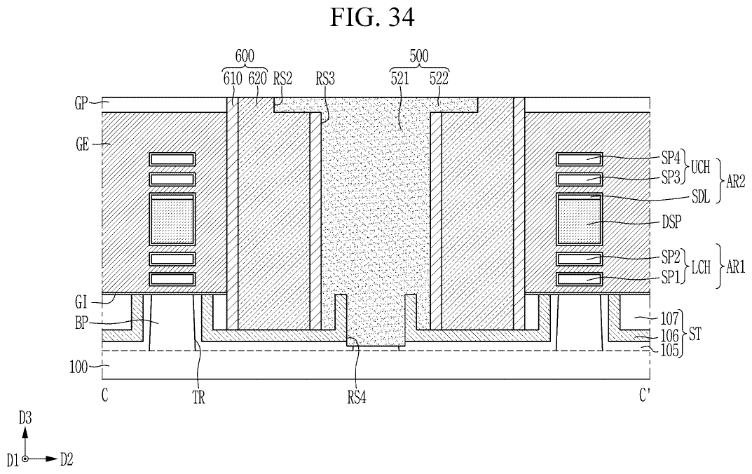

FIG. 31 is a plan view showing a first surface (e.g., a front surface) of a semiconductor device according to an embodiment. FIG. 32 is a cross-sectional view cut along lines A-A′ and D-D′ of FIG. 31 according to an embodiment. FIG. 33 is a cross-sectional view cut along a line C-C′ of FIG. 31 according to an embodiment. FIG. 34 is a cross-sectional view cut along the line C-C′ of FIG. 31 according to some embodiments. In this case, a cross-sectional view cut along a line B-B′ of FIG. 31 may be the same as FIG. 29 so that the cross-sectional view cut along the line B-B′ of FIG. 31 is omitted.

Referring to FIGS. 31 to 33, a separation pattern 500 penetrating a gate pattern GE in the third direction D3 may be formed.

For example, a hard mask pattern may be formed on a gate capping pattern GP, and the gate capping pattern GP may be etched using the hard mask pattern as an etching mask to form a second recess RS2 so that the gate pattern GE is exposed.

Next, the gate pattern GE exposed by the second recess RS2 may be removed, and an upper channel pattern UCH and a lower channel pattern LCH exposed by removal of the gate pattern GE may be removed to form a third recess RS3 and a fourth recess RS4.

According to an embodiment, while the third recess RS3 is formed, a second insulating layer 106 may act as an etching stop layer. For example, the third recess RS3 may be formed from an upper end portion of the gate capping pattern GP to an upper end portion of the second insulating layer 106 along the third direction D3. Specifically, a second portion of the second insulating layer 106 may act as the etching stop layer so that the third recess RS3 is formed on the second portion.

According to an embodiment, the fourth recess RS4 may be formed between second portions of second insulating layers 106. According to an embodiment, the fourth recess RS4 may be formed deeper than the third recess RS3. For example, a lower level of the fourth recess RS4 may be formed lower than a lower level of the second portion of the second insulating layer 106.

According to an embodiment, as shown in FIG. 33, a first portion of the second insulating layer 106 may be removed during the etching process. According to some embodiments, as shown in FIG. 34, the first portion of the second insulating layer 106 may not be removed during the etching process. In this case, the second insulating layer 106 may be disposed within the separation pattern 500. For example, the first portion of the second insulating layer 106 may be buried within the separation pattern 500. Hereinafter, for convenience of description, a process after the first portion of the second insulating layer 106 is removed will be described.

According to an embodiment, the separation pattern 500 may be formed by filling an insulating material within each of the second recess RS2, the third recess RS3, and the fourth recess RS4 and planarizing the insulating material until the hard mask pattern is exposed. Planarization of the insulating material may be performed using an etch back process or a chemical mechanical polishing (CMP) process.

In this case, a body portion 521 of the separation pattern 500 may be formed within the third recess RS3 and the fourth recess RS4, and a protruding portion 522 of the separation pattern 500 may be formed within the second recess RS2. The protruding portion 522 of the separation pattern 500 may be disposed on a gap-fill insulating layer 620. Thereafter, the hard mask pattern may be removed.

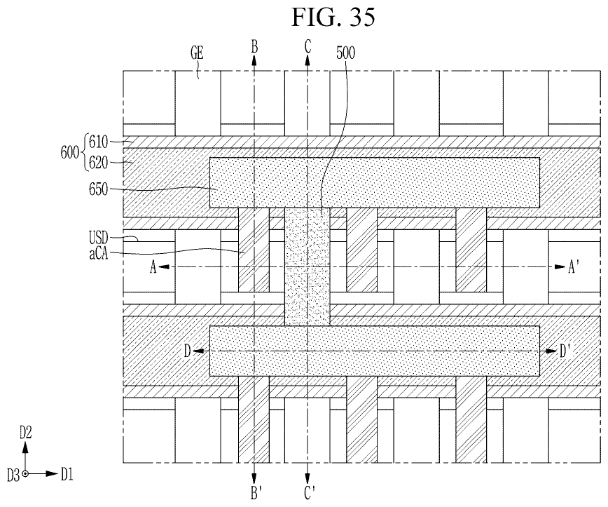

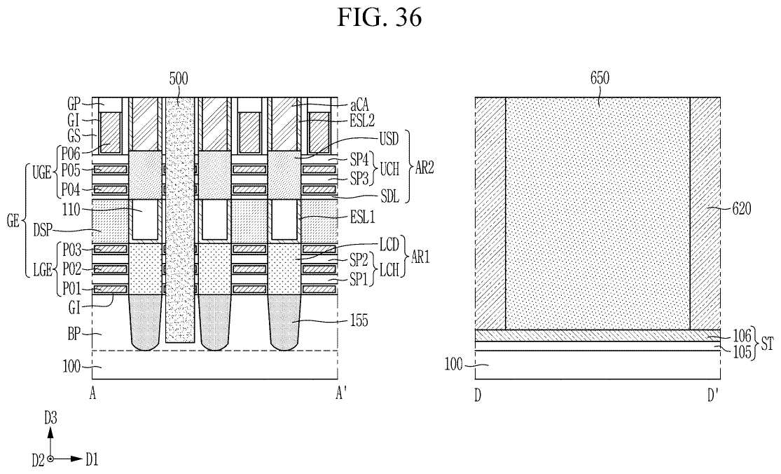

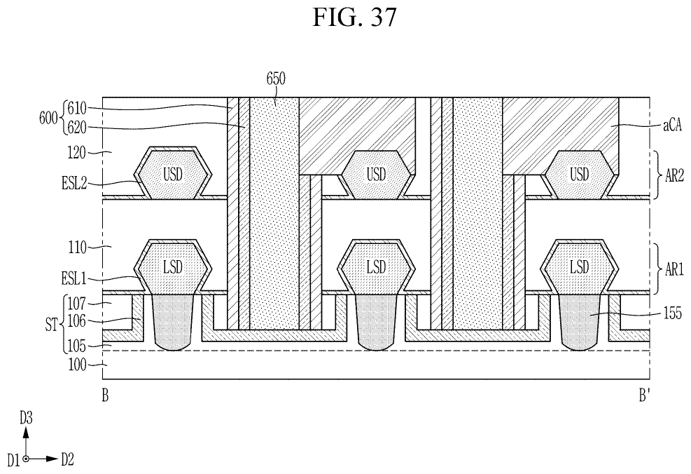

FIG. 35 is a plan view showing a first surface (e.g., a front surface) of a semiconductor device according to an embodiment. FIG. 36 is a cross-sectional view cut along lines A-A′ and D-D′ of FIG. 35 according to an embodiment. FIG. 37 is a cross-sectional view cut along a line B-B′ of FIG. 35 according to an embodiment. FIG. 38 is a cross-sectional view cut along a line C-C′ of FIG. 35 according to an embodiment.

Referring to FIGS. 35 to 38, a through-via 650 extending along the first direction D1 may be formed within a gate cutting pattern 600.

For example, a hard mask pattern may be formed on a gate capping pattern GP and a gap-fill insulating layer 620 of the gate cutting pattern 600 may be etched using the hard mask pattern as an etching mask to form a recess.

In this case, a second insulating layer 106 may act as an etching stop layer. For example, the recess may be formed from an upper end portion of the gate cutting pattern 600 to an upper end portion of the second insulating layer 106 along the third direction D3. Specifically, a second portion of the second insulating layer 106 may act as the etching stop layer so that the recess is formed on the second portion of the second insulating layer 106. For example, the second insulating layer 106 has an etch rate that is different from that of the gap-fill insulating layer 620. Therefore, the second insulating layer 106 may act as the etching stop layer resulting in the lower levels of the recesses being constant. Therefore, the second insulating layer 106 reduces alignment variation along the third direction D3.

Next, the through-via 650 may be formed within an area from which the gap-fill insulating layer 620 is removed. For example, the through-via 650 may be formed by filling a metal within the area from which the gap-fill insulating layer 620 is removed.

According to an embodiment, a lower level of the through-via 650 along the third direction D3 may be substantially the same as an upper level of the second portion of the second insulating layer 106.

As described above, according to the manufacturing method of the semiconductor device according to embodiments, the second portion of the second insulating layer 106 may act as the etching stop layer so that all lower levels of through-vias 650 are substantially the same.

Next, an upper source/drain contact aCA connected to an upper source/drain pattern US may be formed.

For example, a hard mask pattern may be formed on a second interlayer insulating layer 120, and the second interlayer insulating layer 120 may be patterned using the hard mask pattern as an etching mask to form a contact hole penetrating the second interlayer insulating layer 120 in the third direction D3. For example, the patterning may use dry etching. In this case, the contact hole may be disposed at an upper end portion of the upper source/drain pattern USD. While the etching process is performed, at least a portion of the gate cutting pattern 600 may be together removed. Accordingly, the contact hole may be may pass through an insulating liner 610 to be disposed on the gap-fill insulating layer 620.

Next, the upper source/drain contact aCA connected to the upper source/drain pattern USD may be formed by filling a metal within the contact hole. The upper source/drain contact aCA may be connected to the upper source/drain pattern USD in the third direction D3, and may be connected to the through-via 650 in the second direction D2.

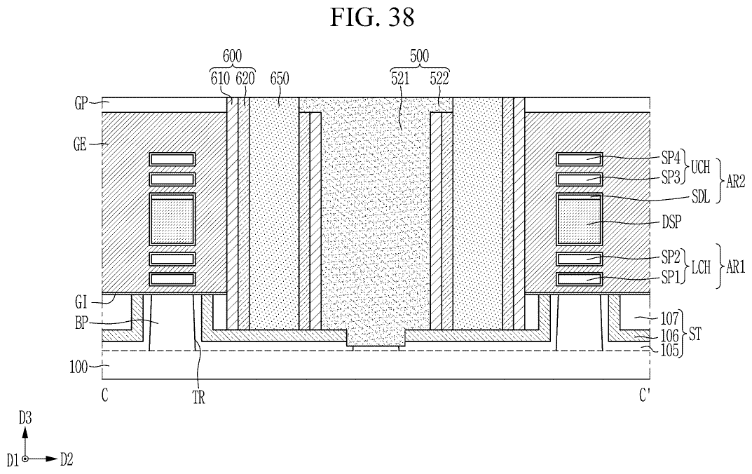

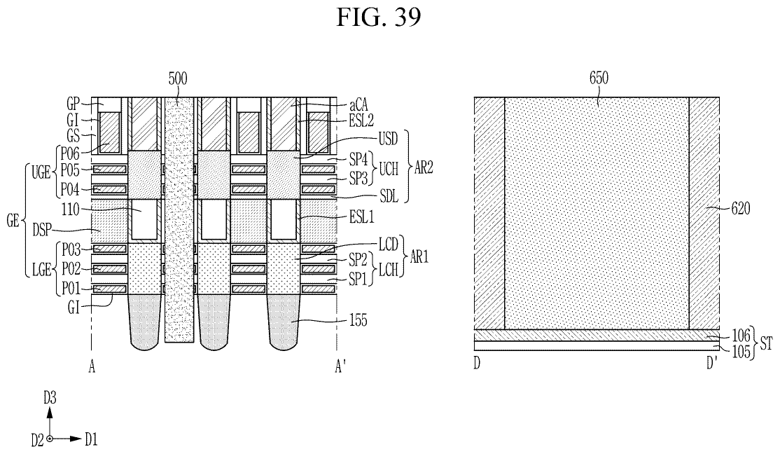

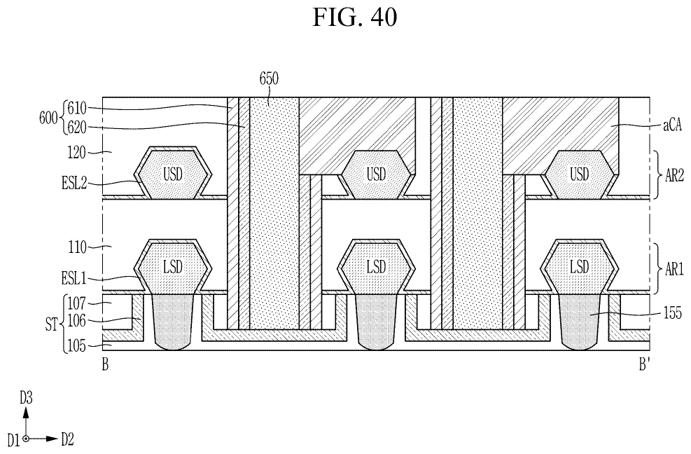

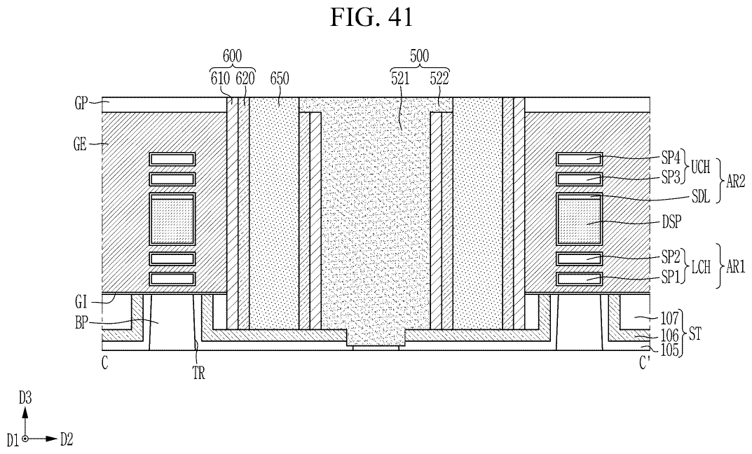

FIG. 39 is a cross-sectional view corresponding to the lines A-A′ and D-D′ of each of FIG. 1 and FIG. 2 according to an embodiment. FIG. 40 is a cross-sectional view corresponding to the line B-B′ of each of FIG. 1 and FIG. 2 according to an embodiment. FIG. 41 is a cross-sectional view corresponding to the line C-C′ of each of FIG. 1 and FIG. 2 according to an embodiment.

Referring to FIGS. 39 to 41, first, a substrate 100 may be removed.

For example, the substrate 100 may be removed by performing an etching process. For example, the etching process may be performed by a wet etching method, but embodiments are not limited thereto.

In this case, because a lower level of a separation pattern 500 in the third direction D3 is higher than a lower level of a dummy source/drain pattern 155, it is possible to prevent the substrate 100 from being sufficiently removed by the separation pattern 500 and to sufficiently remove the substrate 100 until the dummy source/drain pattern 155 is revealed.

Because the substrate 100 is removed until the dummy source/drain pattern 155 is revealed, a lower end portion of the dummy source/drain pattern 155 may have a flat shape.

In some embodiments, if a lower pattern BP includes a semiconductor material such as silicon, the silicon may be removed and may be replaced with silicon oxide. In this regard, the lower pattern BP may be removed while the etching process is performed.

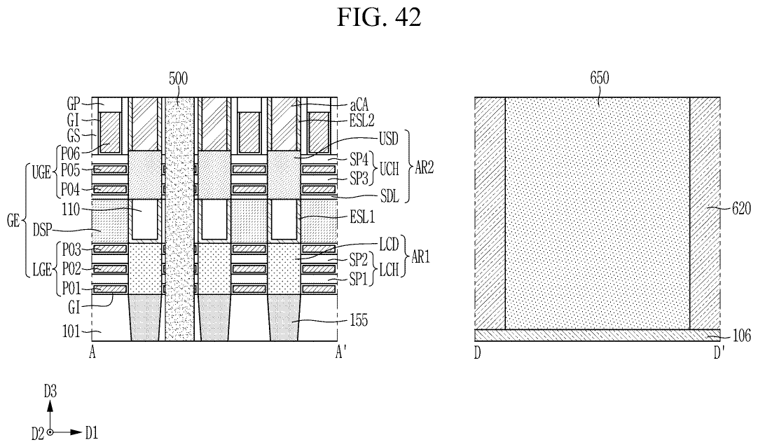

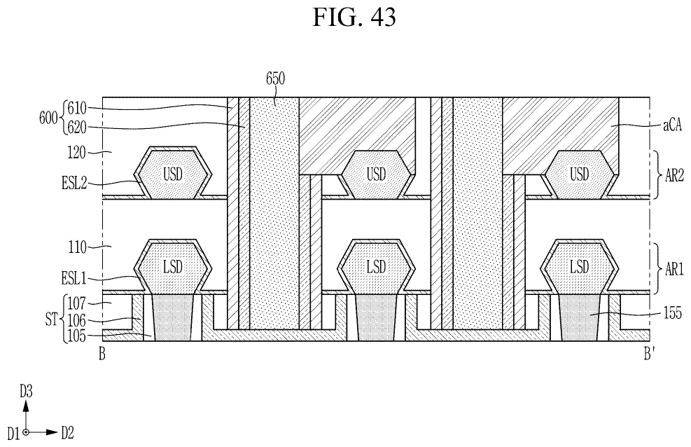

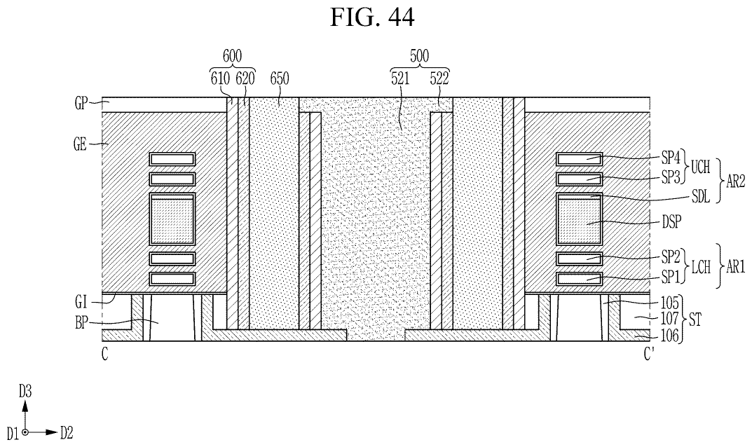

FIG. 42 is a cross-sectional view corresponding to the lines A-A′ and D-D′ of each of FIG. 1 and FIG. 2 according to an embodiment. FIG. 43 is a cross-sectional view corresponding to the line B-B′ of each of FIG. 1 and FIG. 2 according to an embodiment. FIG. 44 is a cross-sectional view corresponding to the line C-C′ of each of FIG. 1 and FIG. 2 according to an embodiment.

Referring to FIGS. 42 to 44, a protruding region 101 may be formed in a region where the substrate 100 and the lower pattern BP are removed.

According to an embodiment, the protruding region 101 may be formed by filling the region where the substrate 100 and the lower pattern BP are removed with an insulating material. For example, the insulating material may include silicon oxide. Accordingly, the protruding region 101 may be formed between device separation layers ST spaced apart in the second direction D2, and may be formed between dummy source/drain patterns 155 spaced apart in the first direction D1.

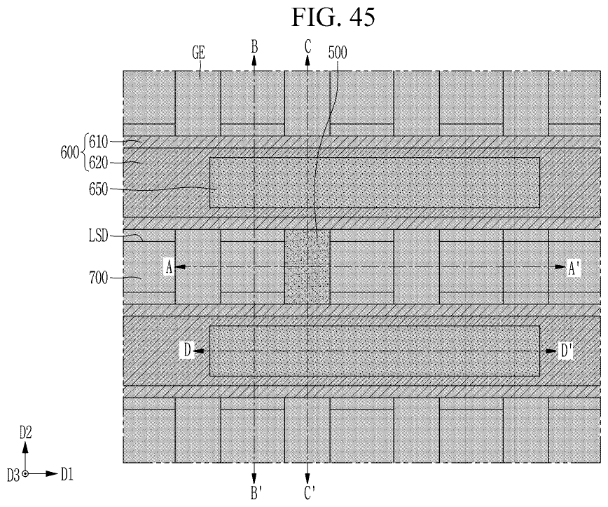

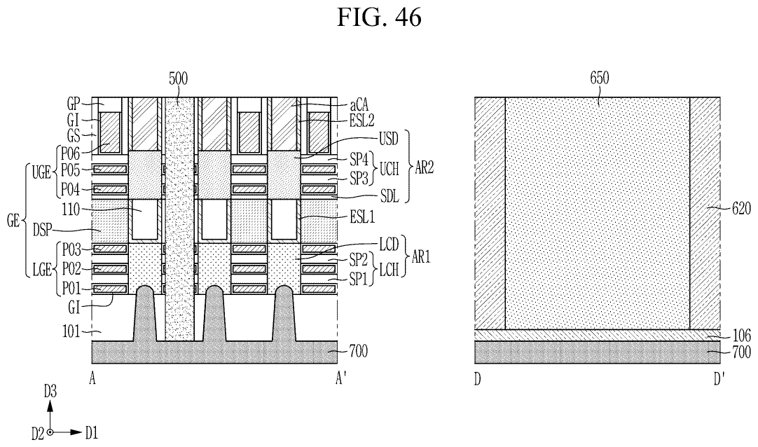

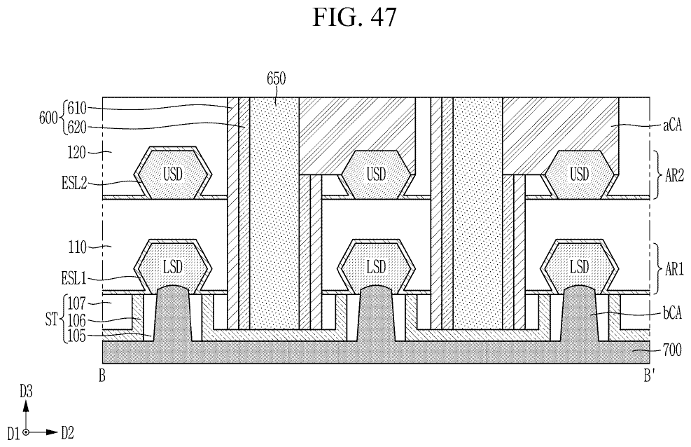

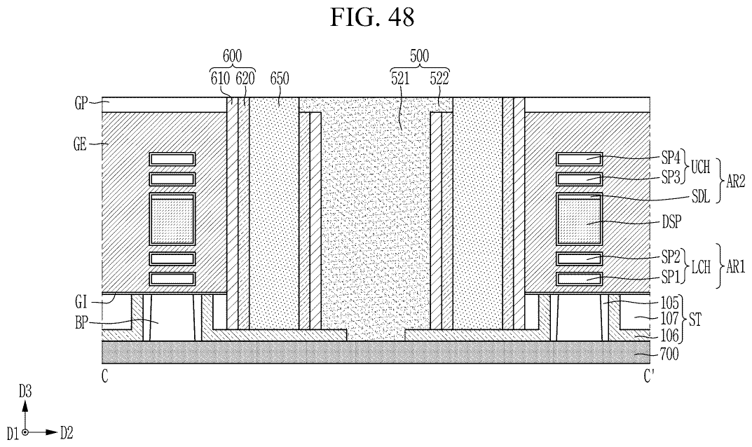

FIG. 45 is a plan view showing a second surface (e.g., a back surface or a rear surface) of a semiconductor device according to an embodiment. FIG. 46 is a cross-sectional view corresponding to lines A-A′ and D-D′ of FIG. 45 according to an embodiment. FIG. 47 is a cross-sectional view corresponding to a line B-B′ of FIG. 45 according to an embodiment. FIG. 48 is a cross-sectional view corresponding to a line C-C′ of FIG. 45 according to an embodiment.

Referring to FIGS. 45 to 48, a portion of a dummy source/drain pattern 155 may be removed to form a lower source/drain contact bCA.

For example, the portion of the dummy source/drain pattern 155 may be removed to form a contact hole through which the lower source/drain pattern LSD is exposed. Subsequently, a metal layer 700 covering a protruding region 101 and a lower surface of a device separation layer ST may be formed. In this case, the metal layer 700 may be filled within the contact hole from which the dummy source/drain pattern 155 is removed.

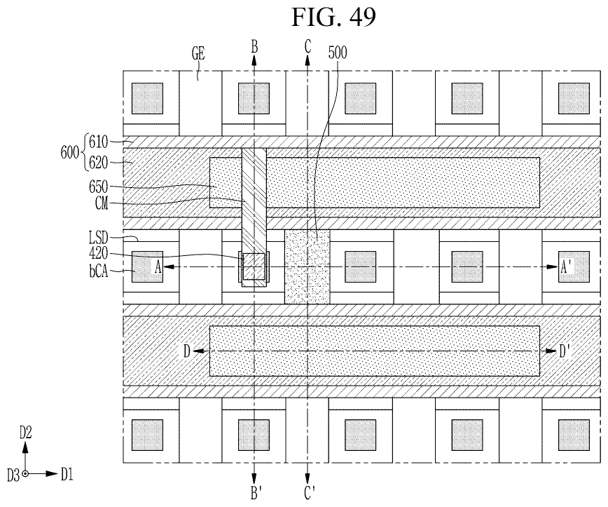

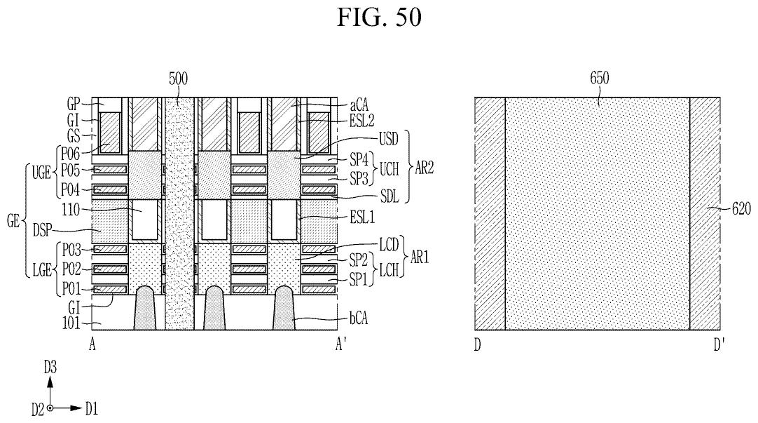

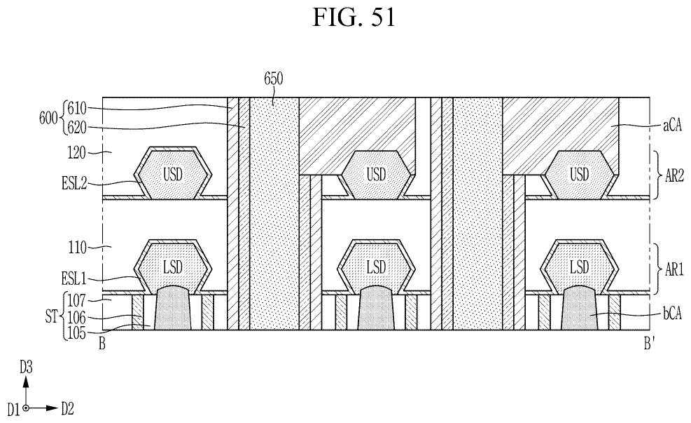

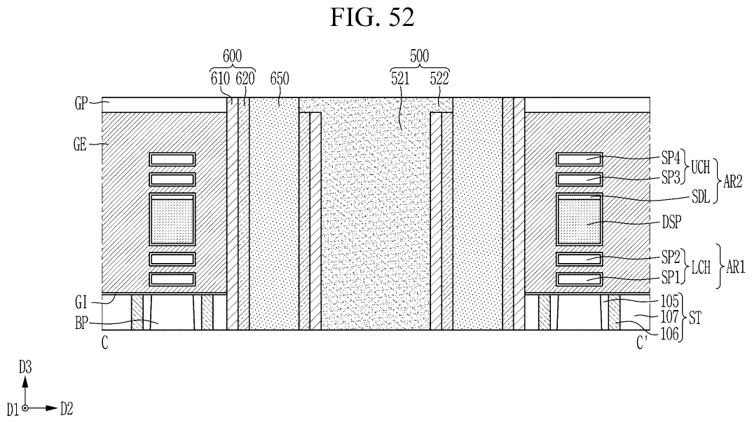

FIG. 49 is a plan view showing a second surface (e.g., a back surface or a rear surface) of a semiconductor device according to an embodiment. FIG. 50 is a cross-sectional view corresponding to lines A-A′ and D-D′ of FIG. 49 according to an embodiment. FIG. 51 is a cross-sectional view corresponding to a line B-B′ of FIG. 49 according to an embodiment. FIG. 52 is a cross-sectional view corresponding to a line C-C′ of FIG. 49 according to an embodiment.

Referring to FIGS. 49 to 52, a lower source/drain contact bCA electrically connected to a lower source/drain pattern LSD may be formed.

According to an embodiment, a metal layer 700 may be planarized until a lower surface of a second portion of a second insulating layer 106 is exposed. Planarization of the metal layer 700 may be performed using an etch back process or a chemical mechanical polishing (CMP) process.

Thereafter, the planarization process may be performed until the second portion of the second insulating layer 106 is removed. In this case, at least a portion of the metal layer 700 may be together removed. In this regard, while the second portion of the second insulating layer 106 is removed, the metal layer 700 having the same level as that of the second portion may be together removed. Specifically, the metal layer 700 and the second portion of the second insulating layer 106 may be sequentially removed. Accordingly, the lower source/drain contact bCA electrically connected to the lower source/drain pattern LSD may be formed.

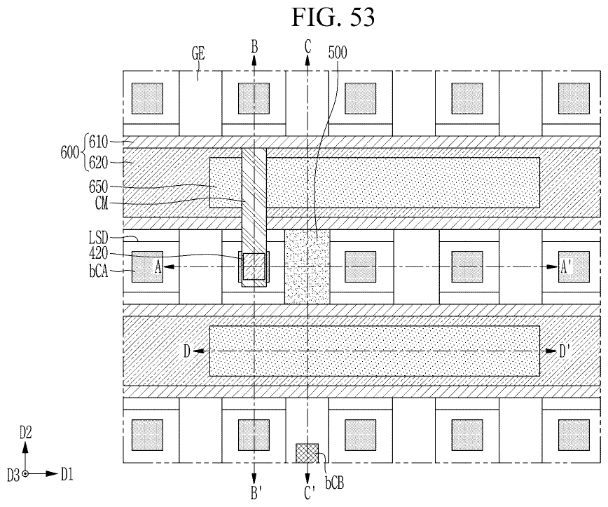

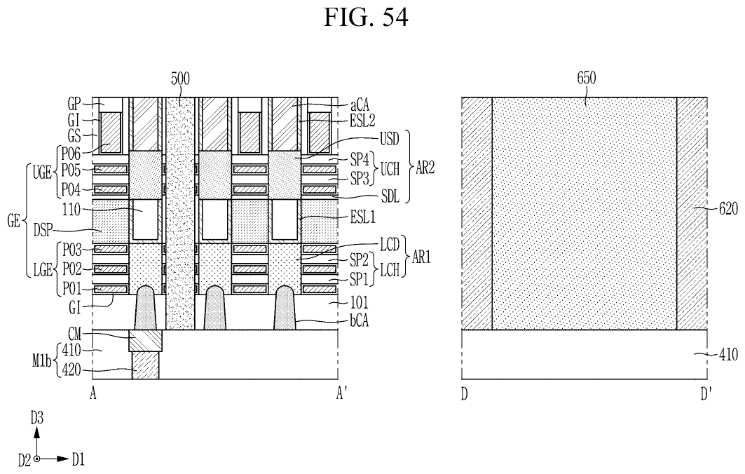

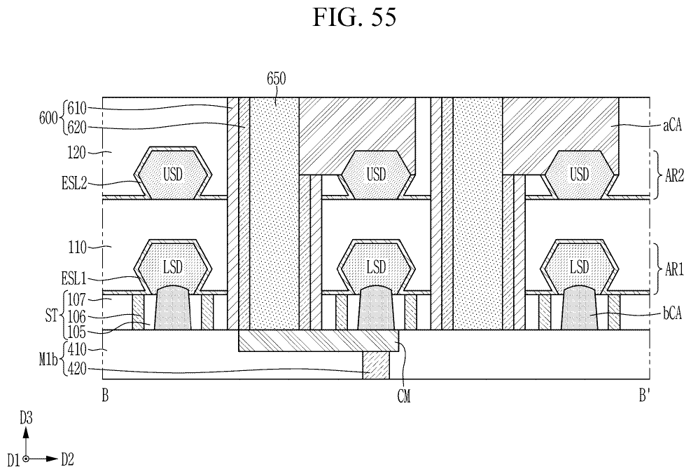

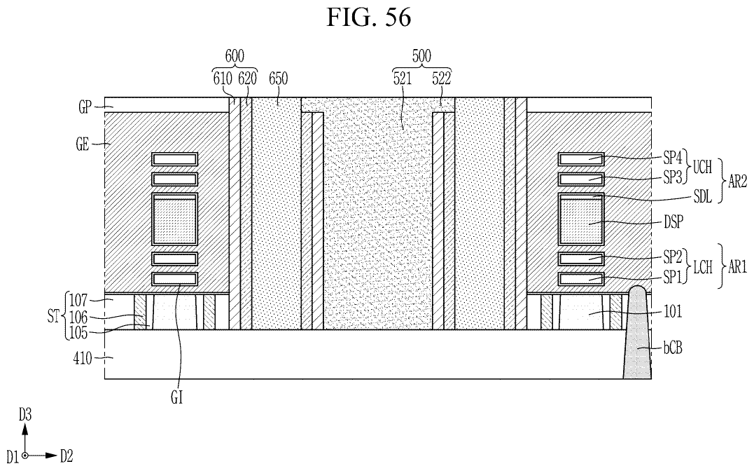

FIG. 53 is a plan view showing a second surface (e.g., a back surface or a rear surface) of a semiconductor device according to an embodiment. FIG. 54 is a cross-sectional view corresponding to lines A-A′ and D-D′ of FIG. 53 according to an embodiment. FIG. 55 is a cross-sectional view corresponding to a line B-B′ of FIG. 53 according to an embodiment. FIG. 56 is a cross-sectional view corresponding to a line C-C′ of FIG. 53 according to an embodiment.

Referring to FIGS. 53 to 56, a lower gate contact bCB connected to a lower gate pattern LGE of a gate pattern GE may be formed, and a lower wiring structure M1b connected to a lower source/drain contact bCA and the lower gate contact bCB may be formed.

For example, a contact hole through which the lower gate pattern LGE of the gate pattern GE is exposed may be formed by removing a portion of a protruding region 101 or a device separation layer ST. In this case, the contact hole may penetrate the protruding region 101 or the device separation layer ST. Subsequently, the lower gate contact bCB that fills the contact hole and is electrically connected to the lower gate pattern LGE of the gate pattern GE may be formed.

Next, a connection portion CM extending from below the lower source/drain contact bCA to below a through-via 650 may be formed. The connection portion CM may be formed by filling a metal after a patterning process is performed. The connection portion CM may be connected to the lower source/drain contact bCA and the through-via 650.

Although a case where the lower source/drain contact bCA, the lower gate contact bCB, and the connection portion CM are formed as a separate process is described above, embodiments are not limited thereto. The lower source/drain contact bCA, the lower gate contact bCB, and the connection portion CM may be simultaneously formed, or the lower gate contact bCB may be first formed and then the lower source/drain contact bCA and the connection portion CM may be formed.

Next, the lower wiring structure M1b including a lower wiring layer 420 electrically connected to the lower source/drain contact bCA and the connection portion CM and a lower insulating layer 410 covering the lower wiring layer 420 may be formed at lower end portions of the device separation layer ST and the protruding region 101. Additionally, the lower wiring structure M1b may be electrically connected to the lower gate contact bCB.

While aspects of embodiments have been particularly shown and described, it will be understood that various changes in form and details may be made therein without departing from the spirit and scope of the following claims.

What is claimed is:

1. A semiconductor device comprising:
a protruding region that extends in a first direction on a first surface of a lower insulating layer;
a device separation layer that is provided at a side of the protruding region, wherein the device separation layer comprises a first insulating layer and a second insulating layer on a side surface of the first insulating layer;
a lower channel pattern and a lower source/drain pattern that are alternately provided along the first direction above the lower insulating layer;
an upper channel pattern above the lower channel pattern;
an upper source/drain pattern above the lower source/drain pattern;
gate patterns that are spaced apart along the first direction and surround the lower channel pattern and the upper channel pattern;
a gate cutting pattern that extends in the first direction between the gate patterns in a second direction intersecting the first direction; and
a through-via that penetrates the gate cutting pattern and extends on the gate cutting pattern in the first direction and a third direction, wherein the third direction intersects the first direction and the second direction.

2. The semiconductor device of claim 1, wherein a lower surface of the second insulating layer is in contact with the first surface of the lower insulating layer.

3. The semiconductor device of claim 1, wherein the first insulating layer and the second insulating layer comprise different materials.

4. The semiconductor device of claim 1, wherein a lower level of the second insulating layer and a lower level of the gate cutting pattern are coplanar.

5. The semiconductor device of claim 1, further comprising a separation pattern between one of lower source/drain patterns comprising the lower source/drain pattern and another of the lower source/drain patterns, and between one of upper source/drain patterns comprising the upper source/drain pattern and another of the upper source/drain patterns,
wherein the one of the lower source/drain patterns is adjacent the other of the lower source/drain patterns along the first direction, and
wherein the one of the upper source/drain patterns is adjacent the other of the upper source/drain patterns along the first direction.

6. The semiconductor device of claim 5, wherein a portion of the separation pattern penetrates the gate cutting pattern and is in contact with the through-via.

7. The semiconductor device of claim 1, further comprising:
an upper source/drain contact on at least one of upper source/drain patterns comprising the upper source/drain pattern, wherein the upper source/drain contact is connected to the upper source/drain pattern; and
a lower source/drain contact below at least one of lower source/drain patterns comprising the lower source/drain pattern, wherein the lower source/drain contact is connected to the lower source/drain pattern,
wherein the upper source/drain contact and the lower source/drain contact are connected to the through-via.

8. The semiconductor device of claim 7, further comprising a connection portion below the lower source/drain contact and the through-via, wherein the connection portion extends in the second direction and connects the lower source/drain contact to the through-via.

9. The semiconductor device of claim 1, wherein the gate cutting pattern comprises a gap-fill insulating layer and an insulating liner.

10. The semiconductor device of claim 9, wherein the gap-fill insulating layer comprises silicon oxide, and the insulating liner comprises silicon nitride.

11. A semiconductor device comprising:
a protruding region that extends in a first direction on a first surface of a lower insulating layer;
a device separation layer that is provided at a side of the protruding region, wherein the device separation layer comprises a first insulating layer and a second insulating layer on a side surface of the first insulating layer;
a lower channel pattern and a lower source/drain pattern that are alternately provided along the first direction above the lower insulating layer;
an upper channel pattern above the lower channel pattern;
an upper source/drain pattern above the lower source/drain pattern;
gate patterns that are spaced apart along the first direction and surround the lower channel pattern and the upper channel pattern;
a gate cutting pattern that extends in the first direction between the gate patterns in a second direction intersecting the first direction; and
a through-via that penetrates the gate cutting pattern and extends in a third direction, wherein the third direction intersects the first direction and the second direction.

12. The semiconductor device of claim 11, wherein the through-via is offset from the gate patterns along the second direction.

13. The semiconductor device of claim 11, wherein a lower surface of the second insulating layer is in contact with the first surface of the lower insulating layer.

14. The semiconductor device of claim 11, wherein the first insulating layer and the second insulating layer comprise different materials.

15. The semiconductor device of claim 11, wherein a lower level of the second insulating layer and a lower level of the gate cutting pattern are coplanar.

16. The semiconductor device of claim 11, further comprising a separation pattern between one of lower source/drain patterns comprising the lower source/drain pattern and another of the lower source/drain patterns, and between one of upper source/drain patterns comprising the upper source/drain pattern and another of the upper source/drain patterns,
wherein the one of the lower source/drain patterns is adjacent the other of the lower source/drain patterns along the first direction, and
wherein the one of the upper source/drain patterns is adjacent the other of the upper source/drain patterns along the first direction.

17. The semiconductor device of claim 16, wherein a portion of the separation pattern penetrates the gate cutting pattern and is in contact with the through-via.

18. The semiconductor device of claim 11, further comprising:
an upper source/drain contact on at least one of upper source/drain patterns comprising the upper source/drain pattern, wherein the upper source/drain contact is connected to the upper source/drain pattern; and
a lower source/drain contact that is below at least one of lower source/drain patterns comprising the lower source/drain pattern and is connected to the lower source/drain pattern,
wherein the upper source/drain contact and the lower source/drain contact are connected to the through-via.

19. A semiconductor device comprising:
a protruding region that extends in a first direction on a first surface of a lower insulating layer;
a device separation layer that is provided at a side of the protruding region, wherein the device separation layer comprises a first insulating layer, a second insulating layer on a side surface of the first insulating layer, and a third insulating layer on a side surface of the second insulating layer;
a lower channel pattern and a lower source/drain pattern that are alternately provided along the first direction above the lower insulating layer;
an upper channel pattern above the lower channel pattern;
an upper source/drain pattern above the lower source/drain pattern;
gate patterns that are spaced apart along the first direction and surround the lower channel pattern and the upper channel pattern;
a gate cutting pattern that extends in the first direction between the gate patterns in a second direction intersecting the first direction; and
a through-via that penetrates the gate cutting pattern and extends on the gate cutting pattern in the first direction and a third direction, wherein the third direction intersects the first direction and the second direction.

20. The semiconductor device of claim 19, wherein the first insulating layer and the third insulating layer comprise a common material, and the first insulating layer and the second insulating layer comprise different materials.
